(19) United States
(12) Patent Application Publication
(10) Pub. No.: US 2026/0155633 A1
(43) Pub. Date: Jun. 4, 2026

(54) MULTIPLE WAVELENGTH LASER DEVICE, METHOD OF MANUFACTURING THE SAME, AND SI -PHOTONICS SYSTEM INCLUDING MULTIPLE WAVELENGTH LASER DEVICE

(71) Applicant: SAMSUNG ELECTRONICS CO., LTD., Suwon-si (KR)

(72) Inventors: Changyoung Park, Suwon-si (KR); Joosung Kim, Suwon-si (KR); Sanghun Lee, Suwon-si (KR)

(73) Assignee: SAMSUNG ELECTRONICS CO., LTD., Suwon-si (KR)

(21) Appl. No.: 19/297,122

(22) Filed: Aug. 12, 2025

(30) Foreign Application Priority Data
Dec. 3, 2024 (KR) 10-2024-0177907

(51) Int. Cl. H01S 5/40; H01S 5/343

(52) U.S. Cl. CPC H01S 5/4087; H01S 5/3432; H01S 5/34366; H01S 5/4012

(57) ABSTRACT

Provided is a multiple wavelength laser device including a plurality of laser devices formed in an array with respect to a plurality of protruding patterns and protruding from a silicon substrate, and having at least one of a width and an arrangement period different from each other, and a plurality of trenches formed in an insulating layer to accommodate each protruding pattern, each laser device including a buffer layer structure formed by crystal growth with respect to a surface of each protruding pattern to fill each trench and formed to a height equal to or higher than the insulating layer, and a light-emitting layer structure formed on the buffer layer structure and having a quantum well structure and configured to emit laser light of different emission wavelength based on at least one of the width and the arrangement period.

### CROSS-REFERENCE TO RELATED APPLICATION

This application claims priority to Korean Patent Application No. 10-2024-0177907, filed on Dec. 3, 2024, in the Korean Intellectual Property Office, the disclosure of which is incorporated by reference herein in its entirety.

### BACKGROUND

### 1. Field

Embodiments of the present disclosure relate to a multiple wavelength laser device and a method of manufacturing the same, and to a silicon photonics system including the multiple wavelength laser device.

### 2. Description of Related Art

Optical interconnect structures for high-speed, large-capacity data transmission require a structure in which optical elements such as light sources and optical transmission lines are integrated into a single substrate. In particular, wideband characteristics are required for large-capacity transmission, and for this purpose, light sources of various wavelengths are required, and accordingly, multiple laser light sources must be applied. Although it is essential to apply a multiple wavelength light source using Group III-V compound semiconductor materials in a silicon-based system, it is difficult to manufacture directly on a silicon substrate, so it may be applied using an external light source or a bonding method. However, bonding multiple laser devices to apply light sources of various wavelengths makes it difficult to accurately align them with the waveguides in the silicon photonics system, and there are also limitations in the individual operation of all laser devices.

### SUMMARY

One or more embodiments provide a multiple wavelength laser device formed by crystal-growth of a laser device composed of a Group III-V compound semiconductor material directly on a silicon substrate, a method of manufacturing the same, and a silicon photonics system including the multiple wavelength laser device.

Additional aspects will be set forth in part in the description which follows and, in part, will be apparent from the description, or may be learned by practice of embodiments.

According to an aspect of one or more embodiments, there is provided a multiple wavelength laser device including a plurality of protruding patterns protruding from a silicon substrate, at least one of a width and an arrangement period of the plurality of protruding patterns being different from each other, an insulating layer on the silicon substrate, the insulating layer including a plurality of trenches configured to accommodate each of the plurality of protruding patterns, at least one of the width and the arrangement period of the plurality of trenches being different from each other, and a plurality of laser devices on a surface of each protruding pattern of the plurality of protruding patterns, wherein each laser device of the plurality of laser devices includes a buffer layer structure formed by crystal growth with respect to the surface of each protruding pattern to fill each trench of the insulating layer, a height of the buffer layer structure being greater than or equal to a height of the insulating layer, and a light-emitting layer structure on the buffer layer structure, the light-emitting layer structure having a quantum well structure configured to emit laser light of different emission wavelength based on at least one of the width and the arrangement period of the plurality of protruding patterns, wherein at least one laser device of the plurality of laser devices has an emission wavelength different from at least one laser device of the remaining laser devices of the plurality of laser devices.

The plurality of protruding patterns and the plurality of trenches accommodating the plurality of protruding patterns may have different widths, and the plurality of laser devices may include light-emitting layer structures that are crystal-grown with respect to each surface of a protruding pattern of the plurality of protruding patterns and have different emission wavelengths from each other.

The plurality of protruding patterns and the plurality of trenches accommodating each of the plurality of protruding patterns may include a plurality of first protruding patterns and a plurality of first trenches accommodating each of the plurality of first protruding patterns having a first arrangement period, and a plurality of second protruding patterns and a plurality of second trenches accommodating each of the plurality of second protruding patterns having a second arrangement period different from the first arrangement period, wherein the plurality of laser devices may include a plurality of first laser devices corresponding to the plurality of first protruding patterns and the plurality of first trenches accommodating the plurality of first protruding patterns, the plurality of first laser devices configured to emit laser light of a first wavelength, and a plurality of second laser devices corresponding to the plurality of second protruding patterns and the plurality of second trenches accommodating the plurality of second protruding patterns, the plurality of second laser devices configured to emit laser light of a second wavelength.

Each surface of each protruding pattern of the plurality of protruding patterns may have a V-shaped groove.

The quantum well structure of the light-emitting layer structure may include quantum barrier layers and quantum well layers alternately stacked multiple times, wherein the quantum barrier layers may include InₓGa_{y}Al_{z}As, where 0.00≤x≤0.50, 0.00≤y, z≤0.95, and wherein the quantum well layers may include InₓGa_{y}Al_{z}As, where 0.20≤x≤0.60, 0.00≤y, z≤0.95.

An indium (In) content of the quantum well layers may be in a range of 0.20 to 0.55, and the In content of the quantum barrier layers may be in a range of 0.00 to 0.45.

Each width of the plurality of trenches may be within a range of 50 to 500 nm, and each emission wavelength of the plurality of laser devices may be within a range of 950 nm to 1750 nm.

The multiple wavelength laser device may further include a waveguide coupler on the silicon substrate and configured to combine a plurality of laser lights emitted from the plurality of laser devices, the waveguide coupler may include a plurality of input terminals corresponding to the plurality of laser devices, respectively.

According to another aspect of one or more embodiments, there is provided a method of manufacturing a multiple wavelength laser device, the method including forming a plurality of protruding pins having at least one of a width and an arrangement period different from each other protruding from a silicon substrate, etching the plurality of protruding pins to a certain depth to form a plurality of protruding patterns having a width corresponding to each of the plurality of protruding pins and protruding from the silicon substrate, forming an insulating layer on the silicon substrate, the insulating layer including a plurality of trenches configured to accommodate each of the plurality of protruding patterns, at least one of the width and the arrangement period of the plurality of trenches being different from each other, and forming a plurality of laser devices on a surface of each protruding pattern of the plurality of protruding patterns, wherein the forming of the plurality of laser devices includes forming a plurality of buffer layer structures that fill the plurality of trenches to a height equal to or higher than a height of the insulating layer by crystal growth with respect to each surface of the plurality of protruding patterns, and forming a plurality of light-emitting layer structures formed the plurality of buffer layer structures and having a quantum well structure configured to emit laser light of different emission wavelengths based on at least one of the width and the arrangement period of the plurality of protruding patterns, and wherein at least one laser device of the plurality of laser devices has a different emission wavelength from at least one laser device of the remaining laser devices.

The plurality of protruding patterns and the plurality of trenches accommodating the plurality of protruding patterns may have different widths, and the plurality of laser devices may include light-emitting layer structures may be configured to emit laser light of different emission wavelengths from each other by crystal-growth with respect to each surface of the plurality of protruding patterns.

The plurality of protruding patterns and the plurality of trenches accommodating each of the plurality of protruding patterns may include a plurality of first protruding patterns and a plurality of first trenches accommodating each of the plurality of first protruding patterns having a first arrangement period, and a plurality of second protruding patterns and a plurality of second trenches accommodating each of the plurality of second protruding patterns having a second arrangement period different from the first arrangement period, wherein the plurality of laser devices may include a plurality of first laser devices corresponding to the plurality of first protruding patterns and the plurality of first trenches accommodating the plurality of first protruding patterns, the plurality of first laser devices being configured to emit laser light of a first wavelength, and a plurality of second laser devices corresponding to the plurality of second protruding patterns and the plurality of second trenches accommodating the plurality of second protruding patterns, the plurality of second laser devices being configured to emit laser light of a second wavelength.

The forming of the plurality of buffer layer structures may include forming an aspect ratio trapping (ART) layer to fill each trench of the insulating layer, and forming a nano-ridge epitaxy (NRE) layer by crystal-growth of the ART layer.

A surface of each protruding pattern of the plurality of protruding patterns may be a V-shaped groove, and the V-shaped groove may be formed by a wet etching process.

The quantum well structure of the plurality of light-emitting layer structures may be formed by alternately stacking a quantum barrier layer and a quantum well layer multiple times, the quantum barrier layer may include InₓGa_{y}Al_{z}As, where 0.00≤x≤0.50, 0.00≤y, z≤0.95, and the quantum well layer may include InₓGa_{y}Al_{z}As, where 0.20≤x≤0.60, 0.00≤y, z≤0.95.

An indium (In) content of the quantum well layer may be in a range of 0.20 to 0.55, and the In content of the quantum barrier layer may be in a range of 0.00 to 0.45.

Each width of the plurality of trenches may be within a range of 50 to 500 nm, and each emission wavelength of the plurality of laser devices may be within a range of 950 nm to 1750 nm.

The method may further include removing a portion of a thickness of the silicon substrate at a position where a waveguide coupler is configured to be formed by etching, forming a support structure on the position, and forming the waveguide coupler on the support structure, wherein the waveguide coupler may include a plurality of input terminals corresponding to the plurality of laser devices, the waveguide coupler being configured to couple a plurality of laser lights emitted from the plurality of laser devices.

According to still another aspect of one or more embodiments, there is provided a silicon photonics system including a multiple wavelength laser device formed by crystal growth in a silicon substrate, and an optical transmission system on the silicon substrate, the optical transmission system being configured to transmit laser light emitted from the multiple wavelength laser device, wherein the multiple wavelength laser device includes a plurality of protruding patterns protruding from the silicon substrate, at least one of a width and an arrangement period of the plurality of protruding patterns being different from each other, an insulating layer on the silicon substrate, the insulating layer including a plurality of trenches configured to accommodate each of the plurality of protruding patterns, at least one of the width and the arrangement period of the plurality of trenches being different from each other, and a plurality of laser devices on a surface of each protruding pattern of the plurality of protruding patterns, wherein each laser device of the plurality of laser devices includes a buffer layer structure formed by crystal growth with respect to the surface of each protruding pattern to fill each trench of the insulating layer, a height of the buffer layer structure being greater than or equal to a height of the insulating layer, and a light-emitting layer structure on the buffer layer structure, the light-emitting layer structure having a quantum well structure configured to emit laser light of different emission wavelength based on at least one of the width and the arrangement period of the plurality of protruding patterns, wherein at least one laser device of the plurality of laser devices has an emission wavelength different from at least one laser device of the remaining laser devices of the plurality of laser devices.

The multiple wavelength laser device may further include a waveguide coupler on the silicon substrate and configured to couple a plurality of laser lights emitted from the plurality of laser devices, the waveguide coupler may include a plurality of input terminals corresponding to the plurality of laser devices.

The optical transmission system may further include at least one of a waveguide configured to transmit laser light from the multiple wavelength laser device, and an optical circuit configured to modulate or split laser light from the multiple wavelength laser device.

### BRIEF DESCRIPTION OF DRAWINGS

The above and other aspects, features, and advantages of embodiments will be more apparent from the following description taken in conjunction with the accompanying drawings, in which:

FIG. 1 is a cross-sectional view illustrating an example of a laser device according to one or more embodiments;

FIG. 2 is a schematic partial perspective view showing a multiple wavelength laser device including the laser device of FIG. 1, according to one or more embodiments;

FIG. 3 is a cross-sectional view illustrating another example of a laser device that may be applied to a plurality of laser device arrays of FIG. 2;

FIG. 4 schematically shows a relationship between a width of a protruding pattern and a trench that accommodates the protruding pattern and an emission wavelength of a laser device to be formed;

FIGS. 5A, 5B, 5C, 5D, 5E, 5F, and 5J illustrate an example method of manufacturing a laser device, according to one or more embodiments;

FIGS. 6A, 6B, 6C, 6D, 6E, and 6F show a method of manufacturing a multiple wavelength laser device according to one or more embodiments;

FIG. 7 is a schematic perspective view showing a multiple wavelength laser device according to one or more embodiments;

FIGS. 8A, 8B, 8C, 8D, 8E, 8F, 8G, and 8H show a method of manufacturing a multiple wavelength laser device according to one or more embodiments;

FIG. 9 is a schematic perspective view showing a multiple wavelength laser device according to one or more embodiments;

FIG. 10 is a schematic perspective view showing a multiple wavelength laser device according to one or more embodiments;

FIG. 11 is a schematic diagram showing a multiple wavelength laser device according to one or more embodiments;

FIG. 12 is a block diagram showing a schematic configuration of a silicon photonics system according to one or more embodiments;

FIG. 13 is a block diagram showing a schematic configuration of a silicon photonics system according to one or more embodiments; and

FIG. 14 is a block diagram showing a schematic configuration of an optoelectronic device according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereafter, embodiments will be described more fully with reference to the accompanying drawings. In the drawings, like reference numerals refer to like elements, and in the drawings, sizes of constituent elements may be exaggerated for clarity and convenience of explanation. The following embodiments described below are merely illustrative, and various modifications may be possible from the embodiments.

Hereinafter, when a position of an element is described using an expression “above” or “on”, the position of the element may include not only the element being “immediately on/under/left/right in a contact manner” but also being “on/under/left/right in a non-contact manner”. Singular forms include the plural forms unless the context clearly indicates otherwise. When a part “comprises” or “includes” an element in the specification, unless otherwise defined, it is not excluding other elements but may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise.

Also, in the specification, the term “units” or “ . . . modules” denote units or modules that process at least one function or operation, and may be realized by hardware, software, or a combination of hardware and software.

In addition, the connecting lines or connecting members between the components shown in the drawings are merely illustrative of functional connections and/or physical or circuit connections. In a practical device, the connections between the components may be represented by various functional connections, physical connections, or circuit connections that may be replaced or added.

All examples or example terms (for example, etc.) are simply used to explain in detail the technical scope of the disclosure, and thus, the scope of the disclosure is not limited by the examples or the example terms as long as it is not defined by the claims.

A multiple wavelength laser device according to one or more embodiments may include an array of a plurality of laser devices. Hereinafter, an example of a multiple wavelength laser device according to one or more embodiments including four or more laser devices is illustrated and described, but is not limited thereto. A multiple wavelength laser device according to one or more embodiments may include two or three laser devices, and at least two laser devices may have different emission wavelengths.

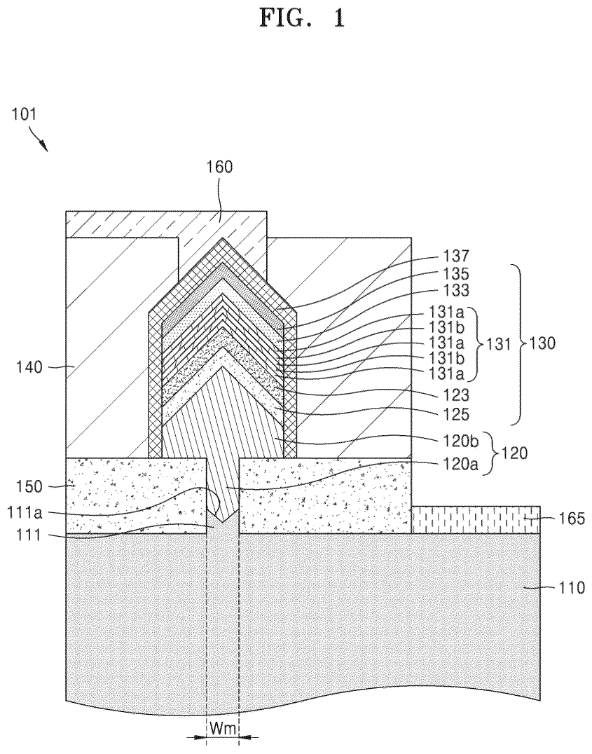

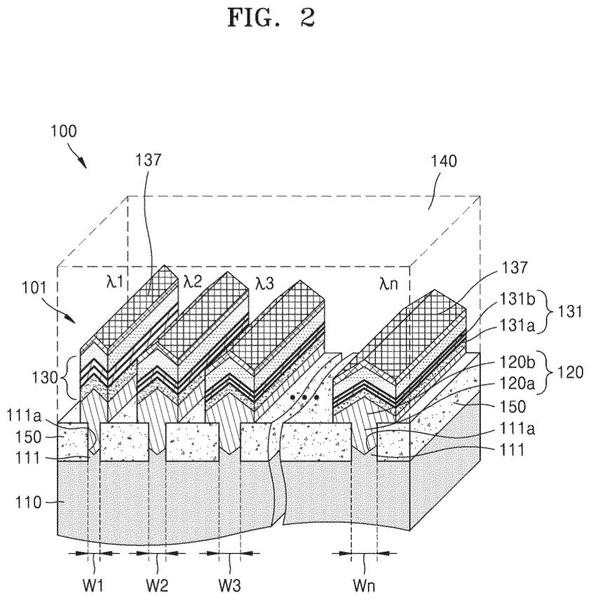

FIG. 1 is a cross-sectional view illustrating an example of a laser device 101 according to one or more embodiments. FIG. 2 is a schematic partial perspective view showing a multiple wavelength laser device 100 including the laser device 101 of FIG. 1, according to one or more embodiments. In FIG. 2, some of layer structures of the laser device 101 are omitted, and a structure for electrical contact is omitted.

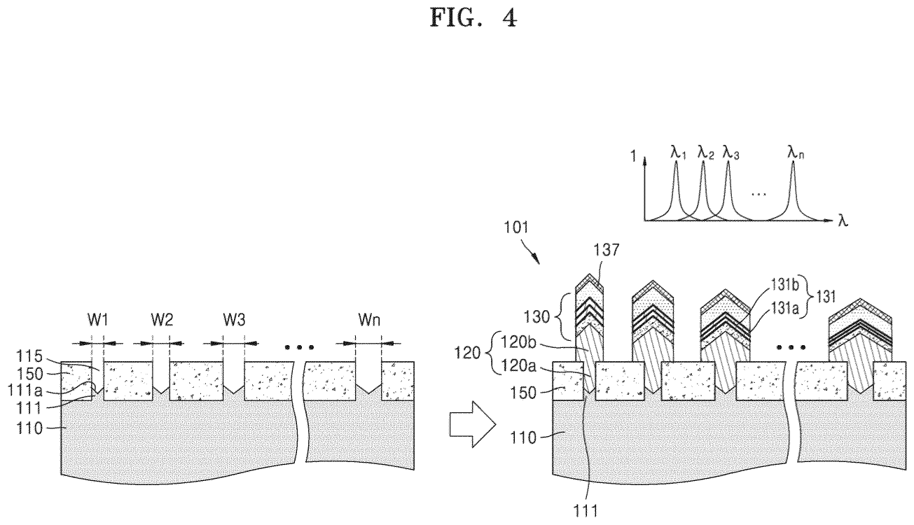

Referring to FIG. 1, the laser device 101 may include a silicon substrate 110, a plurality of protruding patterns 111 formed to protrude in the silicon substrate 110, an insulating layer 150 formed on the silicon substrate 110 to have trenches 115 (see FIG. 4) exposing the protruding patterns 111, a buffer layer structure 120 formed by crystal growth with respect to a surface 111a of the protruding patterns 111 to fill the trenches 115 and to a height higher than the insulating layer 150 in a vertical direction, and a light-emitting layer structure 130 formed on the buffer layer structure 120. In FIG. 1, Wm represents a width of the protruding pattern 111 or the trench 115 that accommodates the protruding pattern 111 in a horizontal direction. In FIG. 1 and FIG. 2, and the diagrams referenced hereinafter, it is illustrated that widths of the protruding pattern 111 and the trench 115 that accommodates the protruding pattern 111 are the same, but embodiments are not limited thereto. For example, the width of the trench 115 may be less or greater than a width of the protruding pattern 111. Hereinafter, a case in which the widths of the protruding pattern 111 and the trench 115 that accommodates the protruding pattern 111 are the same will be described as an example.

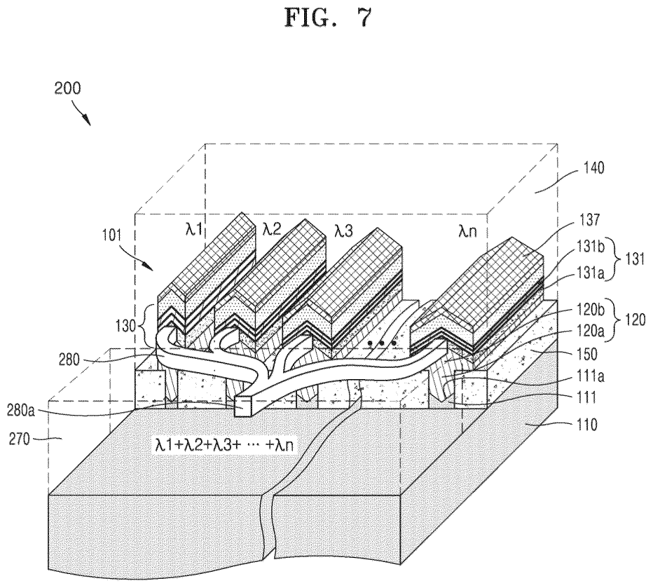

The laser device 101 of FIG. 1 may correspond to each laser device of a plurality of laser devices 101 of the multiple wavelength laser device 100 of FIG. 2 or the multiple wavelength laser devices 200, 300, and 500 according to various embodiments of FIGS. 7, 9, and 10 described below. In Wm, m may be from 1 to n (where n may be an integer greater than or equal to 4).

Referring to FIG. 2, the multiple wavelength laser device 100 may include a silicon substrate 110, a plurality of protruding patterns 111 formed to protrude in the silicon substrate 110, an insulating layer 150 formed on the silicon substrate 110 to have a plurality of trenches 115 (see FIG. 4) for accommodating the protruding patterns 111, and a plurality of laser devices 101 formed as an array by crystal growth with respect to each surface 111a of the plurality of protruding patterns 111. In the plurality of laser devices 101 formed as an array, each laser device 101 may be provided as in FIG. 1, and the emission wavelengths of at least some of the laser devices 101 may be different.

In the plurality of laser devices 101 formed as an array, each laser device 101 may include a buffer layer structure 120 formed by crystal growth with respect to the surface 111a of each protruding pattern 111 to fill each trench 115 of the insulating layer 150 and to a height greater than or equal to the insulating layer 150, and the light-emitting layer structure 130 formed on the buffer layer structure 120 and having a quantum well structure 131 having different emission wavelength characteristics depending on at least one of a width and an arrangement period. In addition, for example, at least one laser device among the plurality of laser devices 101 may have a different emission wavelength from at least one of the remaining laser devices.

To this end, at least one of the plurality of light-emitting layer structures 130 included in the plurality of laser devices 101 may be formed to have a different emission wavelength from at least one of the remaining light-emitting layer structures 130. A buffer layer structure 120 crystal-grown with respect to the surface 111a of the protruding pattern 111 and a light-emitting layer structure 130 epitaxially grown on the buffer layer structure 120 may each form a laser device 101.

The silicon substrate 110 may include silicon. The silicon substrate 110 may be, for example, an n-type silicon substrate. The plurality of protruding patterns 111 may be formed to protrude in the silicon substrate 110 and may be formed to have at least one of a width and an arrangement period different from each other. For example, a plurality of protruding patterns 111 may be formed to have different widths. In addition, each of the plurality of protruding patterns 111 may be formed to have a width within a range of about 50 nm to about 500 nm. The plurality of protruding patterns 111 may include silicon. For example, the plurality of protruding patterns 111 may be formed as a portion of the silicon substrate 110.

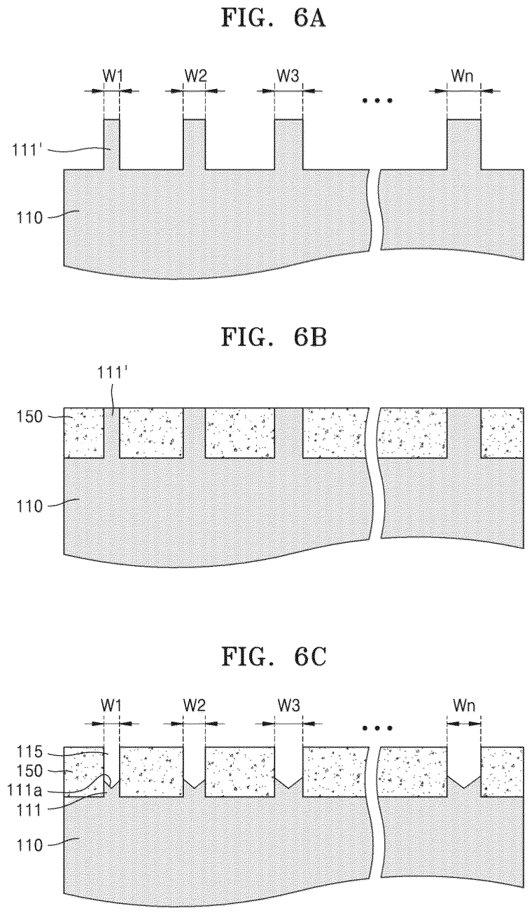

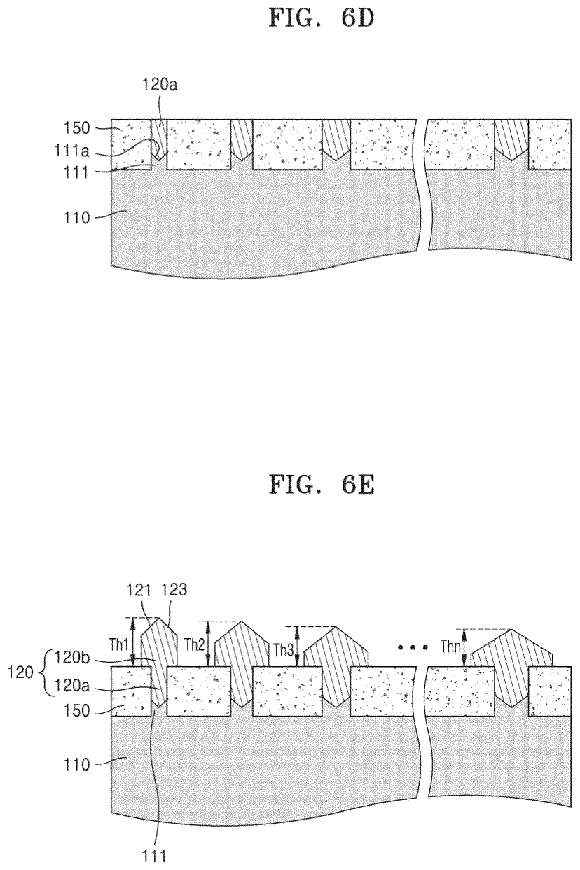

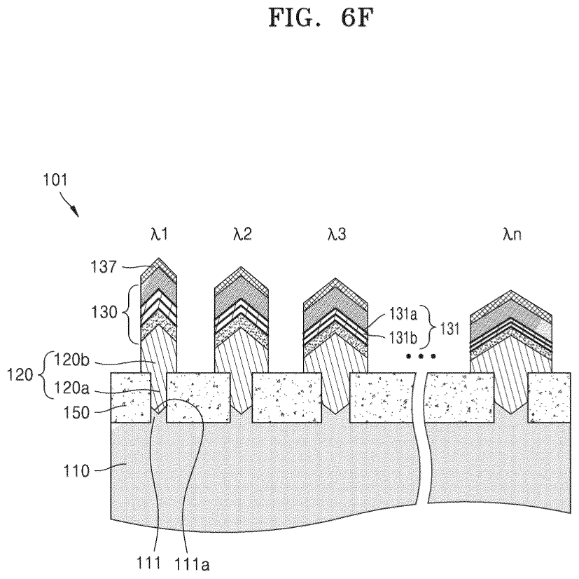

For example, the plurality of protruding patterns 111 may be formed by patterning the silicon substrate 110 to form a plurality of protruding pins 111′ (see FIG. 6A) that protrude from a surface of the silicon substrate 110 and are spaced apart from each other and etching, for example, wet etching the plurality of protruding pins 111′ to a certain depth. In this way, the protruding pattern 111 may include silicon or may be formed of the silicon substrate 110. The surface 111a of the protruding pattern 111 may be formed as a V-shaped groove. The V-shaped groove may be formed by wet etching the protruding pin 111′. The surface 111a of this protruding pattern 111 may correspond to an Si(111) surface (because the surface 111a is a V-shaped groove, an Si(111) surface and an Si(−111) surface are substantially formed, and are referred to as the Si(111) surface, here). A compound semiconductor material having a different lattice constant from silicon, for example, a Group III-V compound semiconductor material, may be crystal-grown with respect to the surface 111a of the protruding pattern 111. By crystal-growing a compound semiconductor material with respect to the surface 111a of the protruding pattern 111, the multiple wavelength laser device 100 may be directly grown on the silicon substrate 110.

At least one of a width and an arrangement period of the plurality of protruding patterns 111 may be different. Therefore the plurality of light-emitting layer structures 130 having different emission wavelengths may be formed in a subsequent process. For example, at least two or more of the plurality of protruding patterns 111 may be formed to have different widths. Therefore, two or more light-emitting layer structures 130 having different emission wavelengths may be formed. At this time, the arrangement period of the plurality of protruding patterns 111 may be constant or different. FIG. 2 and FIG. 4 described below show an example in which the plurality of protruding patterns 111 and the plurality of trenches 115 accommodating the protruding patterns 111 are arranged in a certain cycle. The fixed or variable arrangement period of the protruding patterns 111 may be greater than or equal to the minimum separation distance that allows adjacent laser devices 101 to be formed separate from each other in an epitaxial growth process.

The insulating layer 150 may be formed on the silicon substrate 110. The plurality of trenches 115 (see FIG. 4) that accommodate the plurality of protruding patterns 111 or the plurality of protruding pins 111′ (see FIG. 6A) for forming the plurality of protruding patterns 111 may be formed in the insulating layer 150. For example, a plurality of trenches 115 (see FIG. 4) that have a width corresponding to each of the protruding patterns 111 and are spaced apart from each other may be formed in the insulating layer 150. The surface 111a of the protruding pattern 111 may be exposed through the trench 115, and the buffer layer structure 120 may be crystal-grown with respect to the surface 111a of the protruding pattern 111 through the trench 115.

For example, as shown in FIGS. 6A to 6C described below, in a state that the plurality of protruding pins 111′ (see FIG. 6A) spaced apart from each other are formed in the silicon substrate 110 and the insulating layer 150 is formed on the silicon substrate 110 to be provided on and cover a region between the protruding pins 111′, each of the plurality of protruding pins 111′ may be etched, for example, wet-etched to a certain depth. At this time, each trench 115 may have a width corresponding to each of the protruding patterns 111, for example, the same width, and may be spaced apart from each other.

As another example, the plurality of trenches 115 having a width corresponding to each of the plurality of protruding patterns 111 and exposing regions of the silicon substrate 110 may be formed in an insulating layer 150 on the silicon substrate 110, and the plurality of protruding pins 111′ may be formed on the silicon substrate 110 to fill at least a portion of the depth of each trench 115. The plurality of protruding pins 111′ may include a material including, for example, silicon. Afterwards, when a plurality of protruding pins 111′ are wet etched to a certain depth, the plurality of protruding patterns 111 having the surface 111a formed as a V-shaped groove may be formed. Accordingly, a structure, in which the plurality of protruding patterns 111 protrude in the silicon substrate 110 and accommodated in each trench 115, may be formed. Even in this case, the plurality of trenches 115 may have widths corresponding to each protruding pattern 111, for example, the same width, and may be spaced apart from each other.

As shown in FIG. 2 and FIG. 4 described below, the plurality of protruding patterns 111 may have different widths, and correspondingly, a plurality of trenches 115 that accommodate the plurality of protruding patterns 111 may have different widths.

For example, when the plurality of protruding patterns 111 and the plurality of trenches 115 that accommodate the plurality of protruding patterns 111 have widths of W1, W2, W3, . . . , Wn from the left side to the right side in the horizontal direction, where n is an integer greater than or equal to 4, the widths may satisfy W1≠W2≠W3≠ . . . ≠Wn. Accordingly, when emission wavelengths of the plurality of laser devices 101 including the plurality of buffer layer structures 120 and the plurality of light-emitting layer structures 130 respectively formed with respect to the plurality of protruding patterns 111 and the plurality of trenches 115 accommodating the plurality of protruding patterns 111 are λ1, λ2, λ3, . . . , λn, λ1≠ λ2≠ λ3≠ . . . ≠ λn may be satisfied. The width of each of the plurality of protruding patterns 111 and the plurality of trenches 115 accommodating the plurality of protruding patterns 111 may be determined according to the desired emission wavelength. FIG. 2 shows an example in which the plurality of protruding patterns 111 and the plurality of trenches 115 accommodating the plurality of protruding patterns 111 are arranged at a constant interval, but embodiments are not limited thereto, and at least some of the plurality of protruding patterns 111 and the plurality of trenches 115 accommodating the plurality of protruding patterns 111 may be arranged at different intervals.

In this way, the plurality of protruding patterns 111 and the plurality of trenches 115 accommodating the plurality of protruding patterns 111 may have different widths (W1≠W2≠W3≠ . . . ≠Wn), and the plurality of laser devices 101 including the buffer layer structure 120 and the light-emitting layer structure 130 formed with respect to each of the plurality of protruding patterns 111 and the plurality of trenches 115 accommodating the plurality of protruding patterns 111 may have different emission wavelengths. For example, the emission wavelengths may satisfy λ1≠ λ2≠ 3≠ . . . ≠λn. This is because, as described below, depending on the width of the protruding pattern 111 and the trench 115 accommodating the protruding pattern 111, a thickness of a layer, for example, the quantum well layer 131b, forming the light-emitting layer structure 130 that is epitaxially formed in the subsequent deposition process may vary, and thus the emission wavelength may vary.

Again, referring to FIGS. 1 and 2, the insulating layer 150 may include silicon oxide or silicon nitride. The insulating layer 150 may include, for example, SiO₂ or Si₃N₄. A thickness of the insulating layer 150 may be, for example, greater than or equal to 100 nm. The insulating layer 150 may be formed, for example, by high-temperature deposition on a portion of the silicon substrate 110 where a light source is required. In addition, the insulating layer 150 may be formed at a required position on the silicon substrate 110 for forming a silicon photonics system, as described below.

The plurality of buffer layer structures 120 may be crystal-grown with respect to the surface 111a of each protruding pattern 111. For example, during a buffer layer deposition process, each buffer layer structure 120 may be crystal-grown with respect to the surface 111a of each protruding pattern 111. The buffer layer structure 120 may include a compound semiconductor material including two or more of Group III-V semiconductor materials, such as indium (In), gallium (Ga), aluminum (Al), arsenic (As), or phosphorus (P). As another example, the buffer layer structure 120 may include a multilayer structure of a compound semiconductor material including two or more of In, Ga, Al, As, or P. The buffer layer structure 120 may include, for example, gallium arsenide (GaAs), indium gallium arsenide (InGaAs), and/or indium phosphide (InP). However, embodiments are not limited thereto.

For example, the buffer layer structure 120 may be crystal-grown with respect to the surface 111a of the protruding pattern 111, fill the trench 115 formed in the insulating layer 150, and may be formed to a height higher than the insulating layer 150 in the vertical direction. The buffer layer structure 120 may include an aspect ratio trapping (ART) layer 120a that fills the trench 115 and a nano-ridge epitaxy (NRE) layer 120b formed by crystal growth from the ART layer 120a. The ART layer 120a may correspond to a portion of the buffer layer formed to fill the trench 115, and the NRE layer 120b may correspond to a portion of the buffer layer formed at a height higher than the insulating layer 150 after filling the trench 115 in the vertical direction. The ART layer 120a and the NRE layer 120b may be formed continuously without an interlayer interface, or an interlayer interface may be formed therebetween.

The ART layer 120a and the NRE layer 120b may include a compound semiconductor material in which at least one element is different, or may include the same compound semiconductor material. At this time, the ART layer 120a and the NRE layer 120b may include a compound semiconductor material including two or more of Group III-V semiconductor materials, such as In, Ga, Al, As, or P. As another example, the ART layer 120a and the NRE layer 120b may include a multilayer structure of a compound semiconductor material including two or more of In, Ga, Al, As, or P. The ART layer 120a and the NRE layer 120b may include, for example, GaAs, InGaAs, or InP. However, embodiments are not limited thereto. The ART layer 120a may include, for example, GaAs. The NRE layer 120b may include, for example, InGaAs, such as In_{0.25}GaAs. As another example, the ART layer 120a and the NRE layer 120b may include GaAs.

Due to the plurality of buffer layer structures 120 being formed simultaneously during a deposition process, a layer thickness may vary depending on a width of the protruding pattern 111 and the trench 115 accommodating the protruding pattern 111. For example, as illustrated in FIG. 2, the plurality of protruding patterns 111 and the plurality of trenches 115 that accommodate the plurality of protruding patterns 111 are referred to as first to n^{th} protruding patterns and the first to n^{th} trenches, and their widths are referred to as W1, W2, W3, . . . , Wn. When the width increases from the left to the right, that is, W1<W2<W3< . . . <Wn, the layer thickness of the buffer layer structure 120 that is grown for each of the first to n^{th} protruding patterns 111 and the first to n^{th} trenches that accommodate the first to n^{th} protruding patterns 111 may decrease from the left to the right. Here, the width of each trench 115 may be equal to, less than, or greater than the width of the protruding pattern 111 that is accommodated in the trench 115. For example, the first to n^{th} trenches may have widths of W1 to Wn. Here, a case when the width of each trench 115 is equal to the width of the protruding pattern 111 that is accommodated in the trench 115, is described as an example, but embodiments are not limited thereto.

For example, the widths of the plurality of protruding patterns 111 and the plurality of trenches 115 that accommodate the plurality of protruding patterns 111 may increase from the left to the right side in the horizontal direction. For example, the widths of the first to n^{th} protruding patterns and the first to n^{th} trenches that accommodate the first to n^{th} protruding patterns, respectively, have a relationship of W1<W2<W3< . . . <Wn. In this case, the thickness of the NRE layer 120b of the plurality of buffer layer structures 120 becomes thinner from the left side to the right side in the horizontal direction, and a range in which the NRE layer 120b of the plurality of buffer layer structures 120 is formed may become wider from the left to the right.

For example, the total process time for forming the plurality of buffer layer structures 120 is the same as each other, but the time taken to form the ART layer 120a that fills each of the plurality of trenches 115 varies depending on the width of the trench 115, and therefore, the thickness of the NRE layer 120b formed at a height higher than the insulating layer 150 may vary depending on the width of the trench 115. For example, because it takes more time to fill a relatively wide trench, the time to form the NRE layer 120b formed at a height higher than the insulating layer 150 decreases as the width of the trench 115 increases, and thus, the NRE layer 120b may be formed in a wider region with a less thickness as the width of the trench 115 increases.

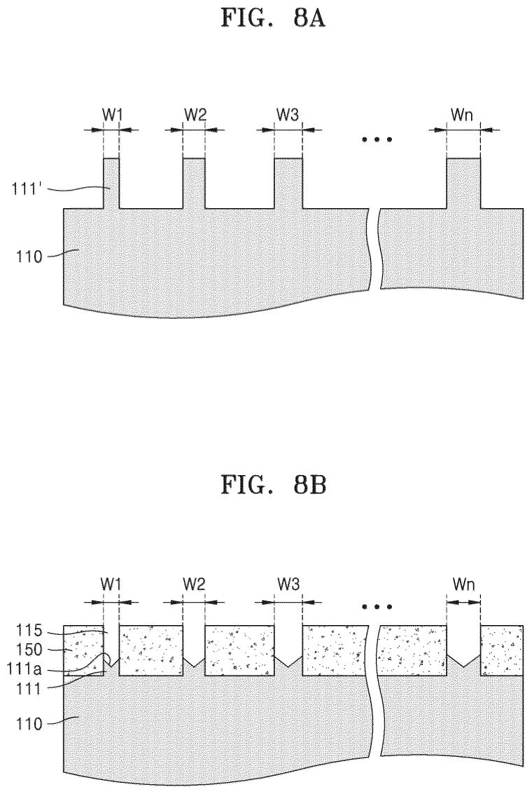

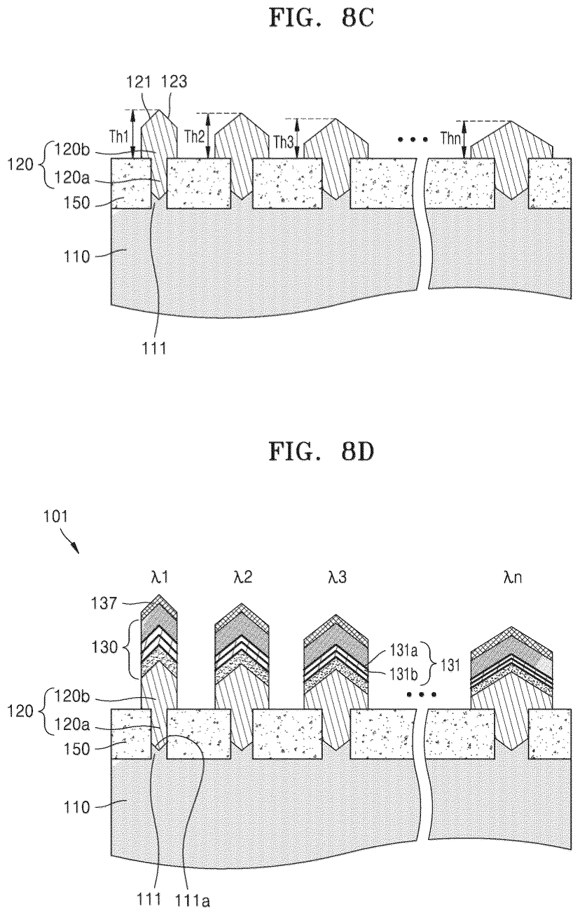

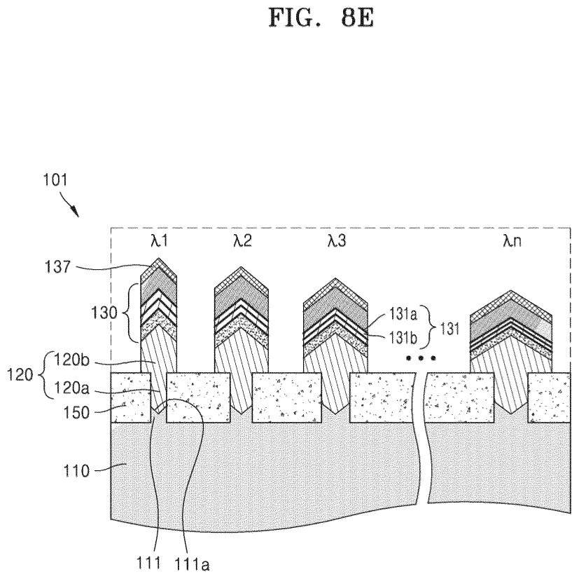

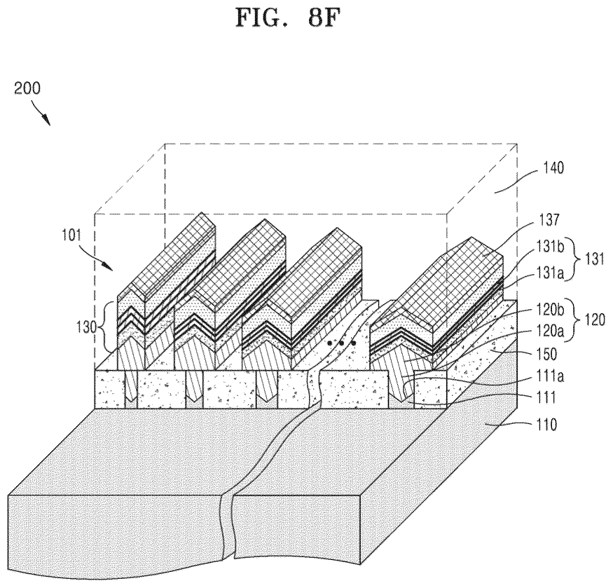

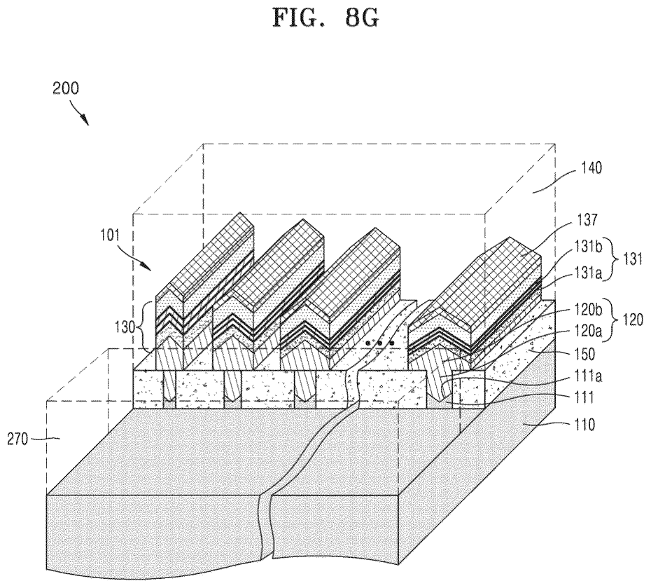

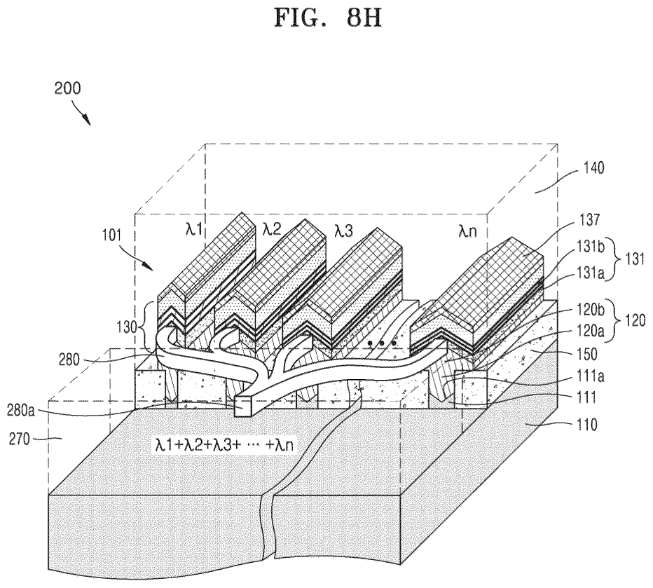

For example, when the ART layers 120a that fill the first to n^{th} trenches, respectively, are referred to as the first to n^{th} ART layers, the NRE layers 120b that are crystal-grown with respect to the first to n^{th} ART layers, respectively, are referred to as the first to n^{th} NRE layers, and the process time for crystal-growing the first to n^{th} ART layers, respectively, is referred to as t1 to tn, because it takes more time to fill a wide trench, there is a relationship of t1<t2<t3< . . . <tn. Accordingly, when the process time of the crystal growth of the first to n^{th} NRE layers is referred to as tR1 to tRn, there is a relationship of tR1>tR2>tR3> . . . >tRn. In addition, when the thicknesses of the first to n^{th} NRE layers formed are Th1, Th2, Th3, . . . , Thn (see FIG. 6E and FIG. 8C), there is a relationship of Th1>Th2>Th3> . . . >Thn. In addition, because the process time for forming each buffer layer structure 120 is the same, t1+tR1=t2+tR2=t3+tR3= . . . =tn+tRn may be satisfied. Therefore, the process time for forming the ART layer 120a may decrease and the process time for forming the NRE layer 120b may increase as the width of the protruding pattern 111 and the trench 115 accommodating the protruding pattern 111 decrease. Conversely, the process time for forming the ART layer 120a may increase and the process time for forming the NRE layer 120b may decrease as the width of the protruding pattern 111 and the trench 115 accommodating the protruding pattern 111 increase. Accordingly, the NRE layer 120b formed at a height higher than the insulating layer 150 may be formed in a relatively narrow region with a thicker thickness as the width of the protruding pattern 111 and the trench 115 accommodating the protruding pattern 111 decreases. In addition, the NRE layer 120b formed at a height higher than the insulating layer 150 may be formed in a wider region with a thinner thickness as the width of the protruding pattern 111 and the trench 115 accommodated in the protruding pattern 111 increases. In this way, depending on the width of the protruding pattern 111 and the trench 115 that accommodates the protruding pattern 111, the region and thickness where the buffer layer structure 120 is epitaxially grown may vary.

A seed layer may be further formed in the surface 111a of the protruding pattern 111. The seed layer may be crystal-grown in the surface 111a of the protruding pattern 111, and the ART layer 120a may be crystal-grown on the seed layer. The seed layer may include a compound semiconductor material including two or more of Group III-V semiconductor materials, such as In, Ga, Al, As, or P. For example, the seed layer may include GaAs. The seed layer may include the same material as the ART layer 120a. For example, the seed layer may be a layer of GaAs crystal grown at a low temperature on the surface 111a of the protruding pattern 111, and the ART layer 120a may be a layer of GaAs crystal grown at a high temperature within the trench 115. When the seed layer includes the same material as the ART layer 120a, the seed layer may not be distinguished from the ART layer 120a. In FIG. 1, FIG. 2, and the diagrams below, the seed layer is omitted.

The plurality of light-emitting layer structures 130 may be, for example, epi-grown on each of the plurality of buffer layer structures 120 and may include the quantum well structure 131, respectively. The quantum well structure 131 may include a multi-quantum well structure. An emission wavelength may be determined by a combination of semiconductor materials forming the quantum well structure 131, the layer thickness, etc. For example, each quantum well structure 131 of the plurality of light-emitting layer structures 130 may be formed to generate light in a wavelength range of greater than or equal to about 950 nm and less than or equal to about 1750 nm.

The quantum well structure 131 may include a quantum barrier layer 131a and a quantum well layer 131b that are alternately stacked multiple times. Each of the quantum barrier layer 131a and the quantum well layer 131b may independently include at least one of In, Ga, Al, As, P, Si, zinc (Zn), and carbide (C). For example, the quantum barrier layer 131a may include InₓGa_{y}Al_{z}As (0.00≤x≤0.50, and 0.00≤y, z≤0.95), and the quantum well layer 131b may include InₓGa_{y}Al_{z}As (0.20≤x≤0.60, and 0.00≤y, z≤0.95). For example, the quantum well layer 131b may include indium (In), and the content of In may be in a range of about 0.20 to about 0.55, for example, about 0.45. The quantum barrier layer 131a optionally may include In, and the content of In may be in a range of about 0.00 to about 0.45, for example, about 0.25. As an example, the quantum well structure 131 may be formed by alternately growing two or more times of the quantum barrier layer 131a including GaAs and the quantum well layer 131b including InGaAs, for example, In_{0.45}GaAs.

In addition, the emission wavelength band of the quantum well structure 131 may be controlled by changing at least one of the shape, material, and thickness of the quantum well layer 131b, and the emission intensity of the quantum well structure 131 may be controlled by changing the number of layers of the quantum well layer 131b.

For example, the quantum well structure 131 of each light-emitting layer structure 130 may be formed by alternately growing the quantum barrier layer 131a of greater than or equal to about 3 nm and the quantum well layer 131b of greater than or equal to about 3 nm or greater than or equal to twice of 3 nm. Each of the quantum barrier layers 131a may be formed to a thickness of greater than or equal to about 3 nm, for example, a thickness of greater than or equal to about 3 nm and less than or equal to about 50 nm, and each of the quantum well layers 131b may be formed to a thickness of greater than or equal to about 3 nm, for example, a thickness of greater than or equal to about 3 nm and less than or equal to about 25 nm. However, this is merely an example, and the quantum barrier layer 131a and the quantum well layer 131b may be formed to various thicknesses.

Because each quantum well structure 131 of the plurality of light-emitting layer structures 130 has different epi growth speeds and area of regions depending on the width of the protruding pattern 111 and the trench 115 that accommodates the protruding pattern 111, for example, the In content in the quantum well layer 131b including InGaAs and the thickness of the quantum well layer 131b including InGaAs may be varied. Thereby, an energy band difference of the InGaAs quantum well layer 131b/GaAs quantum barrier layer 131a may occur, and thus the emission wavelength characteristics may vary. Accordingly, it may be possible to configure the multiple wavelength laser device 100 in which a plurality of laser devices 101 having different emission wavelength characteristics of each light-emitting layer structure 130 as in FIG. 2 are arranged in an array.

Each light-emitting layer structure 130 may further include at least one of a first type semiconductor layer 125 and a first cladding layer 123 between the buffer layer structure 120 and the quantum well structure 131, as illustrated in FIG. 1. In addition, the light-emitting layer structure 130 may further include at least one of a second cladding layer 133 and a second type semiconductor layer 135 on the quantum well structure 131.

For example, as shown in FIG. 1, the first cladding layer 123 may be provided on the first type semiconductor layer 125. Also, the quantum well structure 131 may be provided on the first clad layer 123. For example, the first clad layer 123 may be arranged between the first type semiconductor layer 125 and the quantum well structure 131. The second clad layer 133 may be provided on the quantum well structure 131. In addition, the second type semiconductor layer 135 may be provided on the second clad layer 133. For example, the second clad layer 133 may be arranged between the second type semiconductor layer 135 and the quantum well structure 131.

In this way, the first type semiconductor layer 125, the first clad layer 123, the quantum well structure 131, the second clad layer 133, and the second type semiconductor layer 135 may be sequentially stacked on the buffer layer structure 120. The buffer layer structure 120, the first type semiconductor layer 125, the first clad layer 123, the quantum well structure 131, the second clad layer 133, and the second type semiconductor layer 135 may be formed by, for example, metal-organic chemical vapor deposition (MOCVD), respectively. Here, the first type may be n-type and the second type may be p-type, but are not limited thereto. For example, the first type may be p-type and the second type may be n-type.

The first type semiconductor layer 125 may be provided under the quantum well structure 131. The first type semiconductor layer 125 may include InP. The first type semiconductor layer 125 is not limited to InP and may vary depending on the material of the NRE layer 120b of the buffer layer structure 120. For example, the first type semiconductor layer 125 may include InGaAs, InGaAlAs, or InGaAsP. The first type semiconductor layer 125 may include a first type dopant, and, for example, an n-type dopant may be doped into InP. As the n-type dopant, for example, Si, C, Ge, Se, or Te may be used. However, embodiments are not limited thereto, and the first type semiconductor layer 125 may include a p-type dopant, and for example, Zn or Mg may be used as the p-type dopant.

The second type semiconductor layer 135 may include InP. However, it is not limited thereto, and for example, the second type semiconductor layer 135 may include InGaAs, InGaAlAs, or InGaAsP. The second type semiconductor layer 135 may include a second type dopant, for example, a p-type dopant. For example, Zn or Mg may be used as the p-type dopant. However, embodiments are not limited thereto, and the second type semiconductor layer 135 may include an n-type dopant. For example, Si, C, germanium (Ge), selenium (Se), or tellurium (Te) may be used as the n-type dopant. For example, the first type semiconductor layer 125 may be an n-type layer and may be formed as an n-contact layer, for example, in a thickness range of about 0.01 μm to about 1 μm, and the second type semiconductor layer 135 may include a p-type InGaAs or InP layer and may be formed as a p-contact layer, for example, in a thickness range of about 0.01 μm to about 1 μm.

The first clad layer 123 may perform a role of confining light generated from the quantum well structure 131 together with the second clad layer 133. The first clad layer 123 and the second clad layer 133 may be referred to as separated confinement heterostructure (SCH) layers. The first clad layer 123 and the second clad layer 133 may additionally perform a role of current spreading. A thickness of each of the first clad layer 123 and the second clad layer 133 may be, for example, greater than or equal to about 0.01 μm and less than or equal to about 1 μm.

The first clad layer 123 may include, for example, a material including at least one of In, Ga, Al, As, P, Si, Zn, and C and a predetermined dopant. The first clad layer 123 may include, for example, GaAs, InGaAs, InGaAlAs, InGaAsP, or InP material containing a predetermined dopant. The first clad layer 123 may have a dopant concentration lower than the first type semiconductor layer 125.

When the first type semiconductor layer 125 is n-type, the first clad layer 123 may be an n-type clad layer. In this case, the first clad layer 123 may include an n-type dopant, such as Si, C, Ge, Se, Te, etc. When the first type semiconductor layer 125 is p-type, the first clad layer 123 may be a p-type clad layer. In this case, the first clad layer 123 may include a p-type dopant, such as Zn, magnesium (Mg), etc.

The second clad layer 133 may include, for example, a material including at least one of In, Ga, Al, As, P, Si, Zn, and C and a predetermined dopant. The second clad layer 133 may include, for example, InGaAs, InGaAlAs, InGaAsP, or InP material containing a predetermined dopant. The second clad layer 133 may have a dopant concentration lower than the second type semiconductor layer 135.

When the second type semiconductor layer 135 is p-type, the second clad layer 133 may be a p-type clad layer. In this case, the second clad layer 133 may include a p-type dopant, such as Zn, Mg, etc. When the second type semiconductor layer 135 is n-type, the second clad layer 133 may be an n-type clad layer. In this case, the second clad layer 133 may include an n-type dopant, such as Si, C, Ge, Se, Te, etc.

As illustrated in FIG. 1, the laser device 101 may further include a capping layer 137 formed on the light-emitting layer structure 130. The capping layer 137 is used to prevent damage to at least a portion of the epitaxially grown structure, for example, the NRE layer 120b of the buffer layer structure 120 and the light-emitting layer structure 130, that protrudes above the insulating layer 150 when prior forming the passivation layer 140 in order to manufacture an electrical contact structure for each laser device 101. The capping layer 137 may be formed to be adjacent to and surround the buffer layer structure 120 and the light-emitting layer structure 130 protruding over the insulating layer 150. As another example, the capping layer 137 may be formed to be adjacent to and surround only the light-emitting layer structure 130.

The capping layer 137 may include a predetermined dopant. The capping layer 137 may be, for example, a material in which a predetermined dopant is included in InGaP. When the second type semiconductor layer 135 is p-type, the capping layer 137 may be a p-type capping layer, for example, a p-InGaP layer. In this case, the capping layer 137 may include a p-type dopant, such as Zn, Mg, etc. When the second type semiconductor layer 135 is n-type, the capping layer 137 may be an n-type capping layer, for example, an n-InGaP layer. In this case, the capping layer 137 may include, for example, an n-type dopant such as Si, C, Ge, Se, Te, etc.

The laser device 101 may further include a first type contact layer 165 and a second type contact layer 160. The first type contact layer 165 may be formed, for example, on a portion of a region of the silicon substrate 110. The second type contact layer 160 may be formed on the second type semiconductor layer 135. As shown in FIG. 1, when the capping layer 137 is formed on the second type semiconductor layer 135, the second type contact layer 160 may be formed on the capping layer 137.

As shown in FIG. 1, the first type contact layer 165 may be formed on a portion of the silicon substrate 110. The first type contact layer 165 may include, for example, a semiconductor material and may be doped at a relatively high concentration of first type. When the silicon substrate 110 is an n-type silicon substrate, the first type contact layer 165 may be doped with an n-type dopant at a higher concentration than the silicon substrate 110. When the silicon substrate 110 is a p-type silicon substrate, the first type contact layer 165 may be doped with a p-type dopant at a higher concentration than the silicon substrate 110. An electrode may be further formed on the first type contact layer 165. As another example, the first type contact layer 165 may be made of an electrode material, for example, a highly conductive metal or various conductive materials.

The second type contact layer 160 may include the same material as the second type semiconductor layer 135 or the capping layer 137, and the second type contact layer 160 may be doped with a dopant at a higher concentration than the second type semiconductor layer 135. When the second type semiconductor layer 135 is p-type, the second type contact layer 160 may be doped with a p-type dopant at a higher concentration than the second type semiconductor layer 135 or the capping layer 137. When the second type semiconductor layer 135 is n-type, the second type contact layer 160 may be doped with an n-type dopant at a higher concentration than the second type semiconductor layer 135 or the capping layer 137. An electrode may be further formed on the second type contact layer 160. As another example, the second type contact layer 160 may be made of an electrode material, for example, a highly conductive metal or various conductive materials.

A passivation layer 140 that is adjacent to and surrounds each laser device 101 of an array of a plurality of laser devices 101 and may be used as a support layer for forming the second type contact layer 160 may be further formed. The passivation layer 140 may be provided to be adjacent to and surround the buffer layer structure 120 and the light-emitting layer structure 130. The passivation layer 140 may include, for example, polyimide, silicon oxide (SiO₂), or silicon nitride (SiN_{X}).

A trench for forming a contact with the second type contact layer 160 to the light-emitting layer structure 130 may be formed in the passivation layer 140, and the second type contact layer 160 may be formed to fill the trench of the passivation layer 140 and extend by using the passivation layer 140 as a support layer.

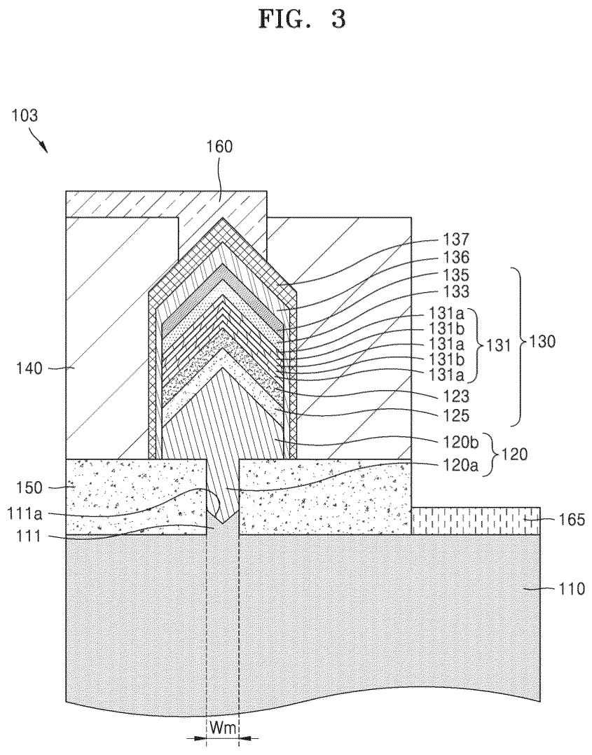

FIG. 3 is a cross-sectional view illustrating another example of a laser device 103 that may be applied to an array of a plurality of laser devices 101 of FIG. 2. The laser device 103 according to one or more embodiments is different from the laser device 101 of FIG. 1 in that the laser device 103 further includes a current spreading layer 136.

For example, each laser device 101 of the array of a plurality of laser devices 101 of FIG. 2 may further include the current spreading layer 136 between the second type semiconductor layer 135 and the capping layer 137 of the light-emitting layer structure 130, as in the laser device 103 illustrated in FIG. 3. The current spreading layer 136 may be formed to be adjacent to and surround a portion of the buffer layer structure 120 and the light-emitting layer structure 130 on the insulating layer 150, and in this case, the capping layer 137 may be formed to be adjacent to and surround the buffer layer structure 120 and the light-emitting layer structure 130 with the current spreading layer 136 therebetween.

In this way, the multiple wavelength laser device 100 may include an array of a plurality of laser devices 101, and each laser device 101 may be provided as described with reference to FIG. 1 or FIG. 3, may or may not include the current spreading layer 136, and the emission wavelengths of the laser devices 101 may be different from each other.

The plurality of laser devices 101 included in the multiple wavelength laser device 100 may be formed with respect to each of, for example, the protruding patterns 111 having a width of W1, W2, W3, . . . , Wn, where n is an integer greater than or equal to 4, and the trenches 115 accommodating each of the protruding patterns 111, and may emit laser light having wavelengths of λ1, λ2, λ3, . . . , λn. For example, the laser device 101 including the light-emitting layer structure 130 formed with respect to the protruding pattern 111 having a width of W1 and the trench 115 accommodating the protruding pattern 111 may emit laser light having a wavelength of λ1. The laser device 101 including the light-emitting layer structure 130 formed with respect to the protruding pattern 111 having a width of W2 and the trench 115 accommodating the protruding pattern 111 may emit laser light having a wavelength of λ2. The laser device 101 including the light-emitting layer structure 130 formed with respect to the protruding pattern 111 having a width of W3 and the trench 115 accommodating the protruding pattern 111 may emit laser light having a wavelength of λ3. The laser device 101 including the light-emitting layer structure 130 formed with respect to the protruding pattern 111 having a width of Wn and the trench 115 accommodating the protruding pattern 111 may emit laser light having a wavelength of λn.

When the plurality of protruding patterns 111 and the plurality of trenches 115 accommodating the plurality of protruding patterns 111 have different widths (W1≠W2≠W3≠ . . . ≠Wn), the plurality of light-emitting layer structures 130 formed with respect to each of the plurality of protruding patterns 111 and trenches 115 accommodating the plurality of protruding patterns 111 and the plurality of laser devices 101 including each of them, may have different emission wavelengths. For example, λ1≠ λ2≠ λ3≠ . . . ≠λn may be satisfied. This is because, depending on the width of the protruding pattern 111 and the trench 115 that accommodates protruding pattern 111, thickness and the content of a predetermined element in the quantum well layer 131b of the light-emitting layer structure 130, for example, thickness and the content of In in the InGaAs quantum well layer 131b of the light-emitting layer structure 130, formed in a subsequent epitaxial growth process, are grown differently, and an energy band difference of the quantum well layer 131b/quantum barrier layer 131a occurs, resulting in changing of emission wavelength characteristics. Therefore, a parallel-type multi-wavelength laser array with different wavelength characteristics may be implemented. In this way, a multi-wavelength laser array may be grown directly on a silicon substrate.

FIG. 4 schematically shows a relationship between the width of the protruding pattern 111 and the trench 115 that accommodates the protruding pattern 111 and an emission wavelength of the laser device 101 to be formed. The left diagram of FIG. 4 shows a structure in which protruding patterns 111 having different widths of W1, W2, W3, . . . , Wn, where n is an integer greater than or equal to 4, are formed to protrude on a silicon substrate 110, and trenches 115 that accommodate each of the protruding pattern 111 are formed in an insulating layer 150 on the silicon substrate 110, which may correspond to a step prior to depositing the buffer layer in a manufacturing process of the multiple wavelength laser device 100 according to one or more embodiments. The lower right diagram of FIG. 4 corresponds to a cross-sectional view of the multiple wavelength laser device 100 illustrated in FIG. 2, and the passivation layer 140 and the electrode structure for electrical contact are omitted. In the multiple wavelength laser device 100 including the array of the plurality of laser devices 101, each laser device 101 may be formed as the laser device 101 of FIG. 1 or the laser device 103 of FIG. 3.

When the widths of the plurality of protruding patterns 111 and the plurality of trenches 115 accommodating the plurality of protruding patterns 111 are different each other under the condition of W1<W2<W3< . . . <Wn, the emission wavelengths λ1, λ2, λ3, . . . , λn of the plurality of laser devices 101 formed with respect to each protruding pattern 111 and each trench 115 accommodating the protruding pattern 111 may be different from each other. For example, as may be seen from the graph illustrated in the upper right of FIG. 4, the emission wavelengths may have a relationship of λ1<λ2<λ3< . . . <λn. For example, the wider the width of the protruding pattern 111 and the trench 115 that accommodates the protruding pattern 111, the longer the emission wavelength of the laser device 101 formed with respect to the corresponding protruding pattern 111 and the trench 115 that accommodates the protruding pattern 111. The smaller the width of the protruding pattern 111 and the trench 115 that accommodates the protruding pattern 111, the shorter the emission wavelength of the laser device 101 formed with respect to the protruding pattern 111 and the trench 115 that accommodates the protruding pattern 111.

This is because, as shown in FIGS. 2 and 4, when the width of the protruding pattern 111 and the trench 115 that accommodates the protruding pattern 111 is smaller, the buffer layer structure 120 may be formed as a thicker layer in a relatively narrow region, and accordingly, in the quantum well structure 131 of the light-emitting layer structure 130, for example, the quantum well layer 131b, is also formed as a thicker layer. In addition, when the width of the protruding pattern 111 and the trench 115 that accommodates the protruding pattern 111 is large, the buffer layer structure 120 is formed as a thin layer over a wide region, and accordingly, in the quantum well structure 131 of the light-emitting layer structure 130, for example, the quantum well layer 131b, is also formed as a thinner layer.

The multiple wavelength laser device 100 according to one or more embodiments described with reference to FIGS. 1 to 4 may be directly grown on a portion that requires a multiple wavelength laser device on a silicon substrate 110, thereby implementing a relatively small, low-power multiple wavelength laser device. The multiple wavelength laser device 100 according to one or more embodiments may be implemented in a chip size, and thus, it may be implemented in a smaller size compared to a size of an existing external light source system or a hybrid light source in which a bonding method is applied.

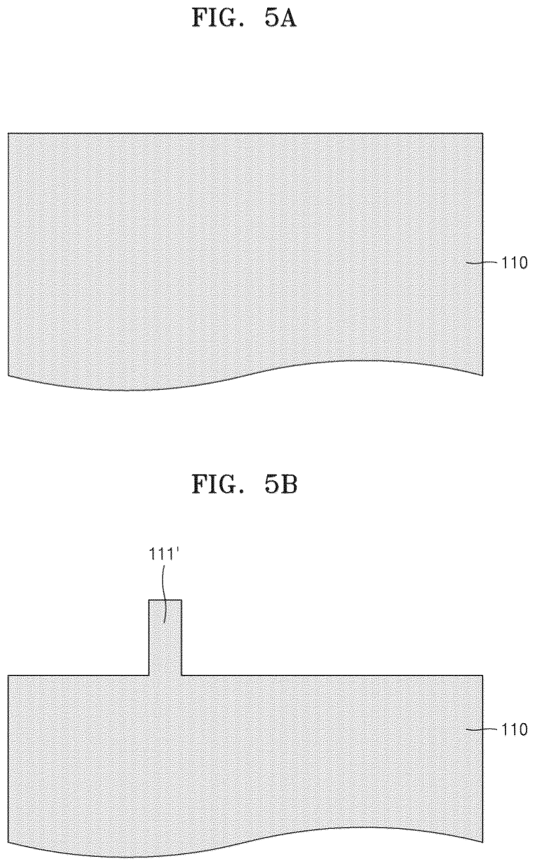

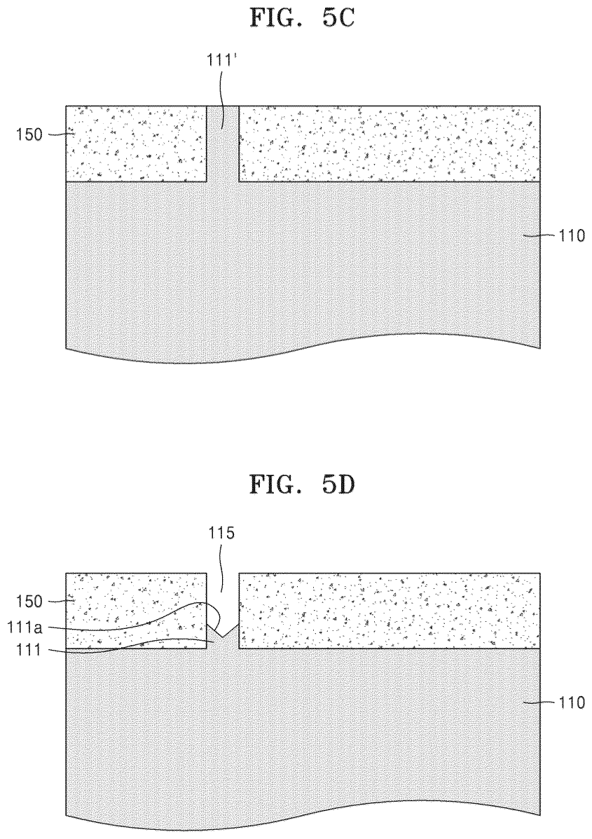

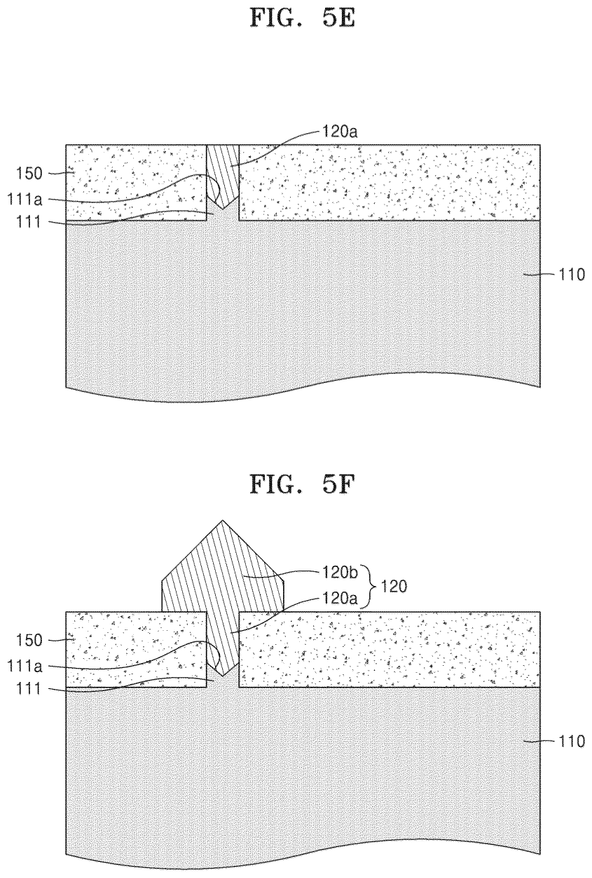

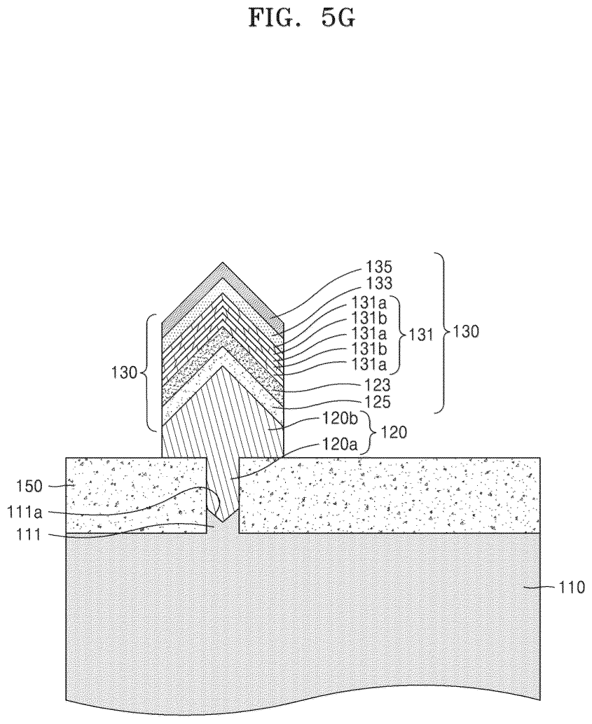

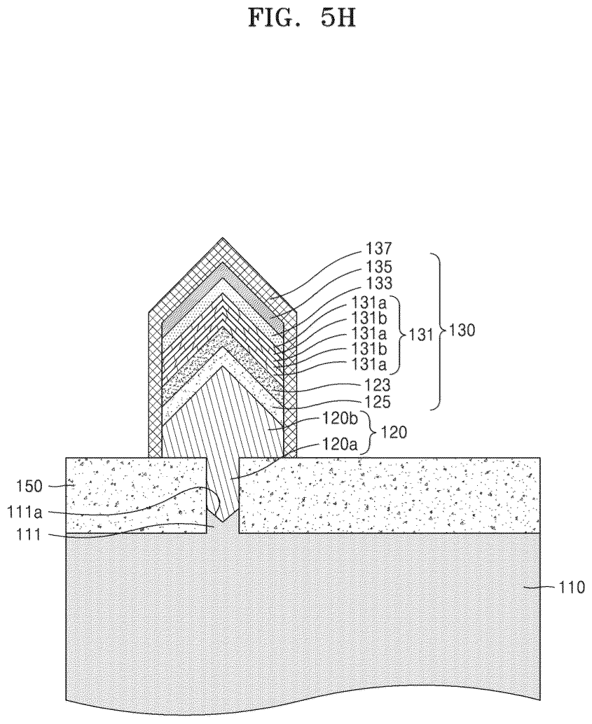

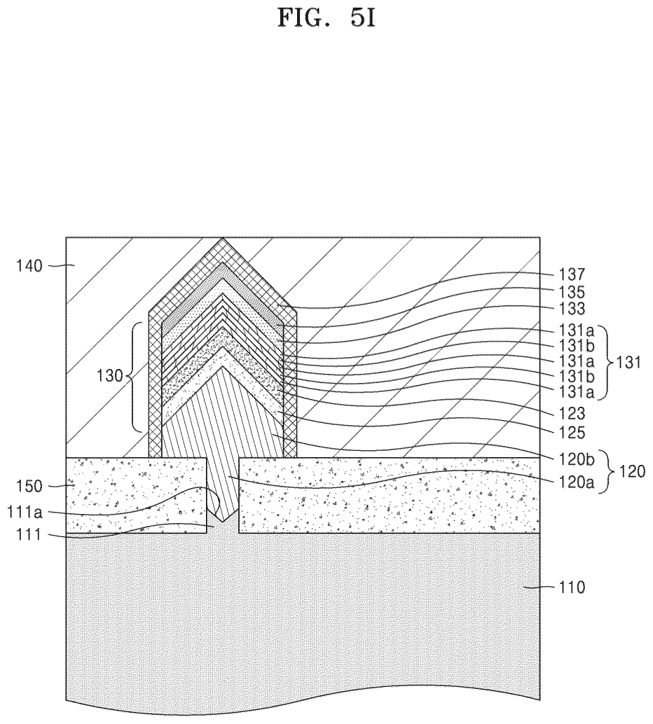

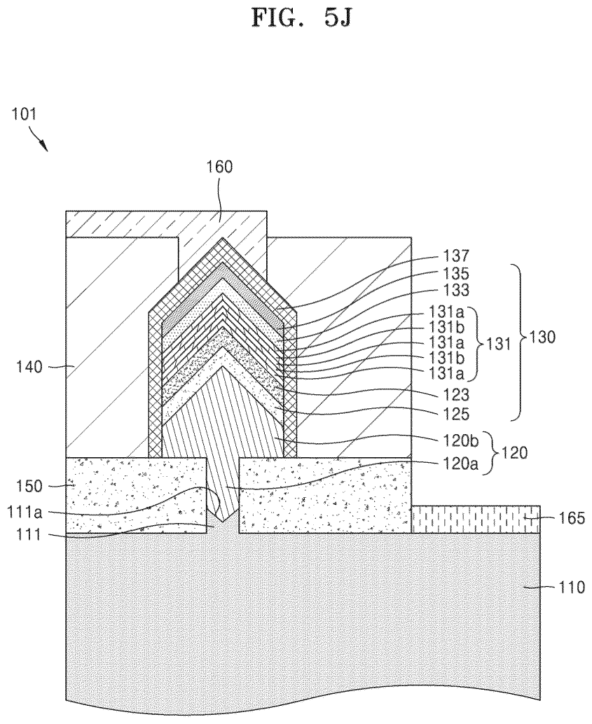

FIGS. 5A to 5J illustrate an example of a method of manufacturing a laser device 101, according to one or more embodiments. The laser device 101 illustrated in FIG. 1 or the laser device 103 illustrated in FIG. 3 may be formed by the manufacturing method of FIGS. 5A to 5J.

Referring to FIGS. 5A to 5C, a silicon substrate 110 may be patterned to form a protruding pin 111′ that protrudes with respect to a surface of the silicon substrate 110 and has a width, and an insulating layer 150 may be formed on the silicon substrate 110. The insulating layer 150 may be formed, for example, by high-temperature deposition on a portion of the silicon substrate 110 where a light source is required. The insulating layer 150 may be formed in addition to the portion where the light source is required on the silicon substrate 110 as needed for implementing a silicon photonics system including the laser device 101 or the multiple wavelength laser device 100 according to one or more embodiments. The insulating layer 150 may include, for example, SiO₂ or Si₃N₄, and may be formed to have a thickness of, for example, greater than or equal to 100 nm. The silicon substrate 110 and the insulating layer 150 may be substantially the same as the silicon substrate 110 and the insulating layer 150 described above with reference to FIGS. 1 to 4. The protruding pin 111′ may be formed of, for example, the silicon substrate 110.

Referring to FIG. 5D, the protruding pin 111′ may be etched, for example, wet etched to a certain depth. As a result, a structure may be obtained in which a protruding pattern 111 protruding with respect to the silicon substrate 110 is accommodated in the trench 115 formed in the insulating layer 150. At this time, a surface 111a of the protruding pattern 111 may be formed as a V-shaped groove. The surface 111a of the protruding pattern 111 may correspond to an Si (111) surface because the surface 111a is a V-shaped groove, an Si (111) surface and an Si (−111) surface are substantially formed. The wet etching process may be performed, for example, using a KOH or TMAH solution as an etching medium.

Referring to FIGS. 5E and 5F, a buffer layer structure 120 may be crystal-grown with respect to the surface 111a of the protruding pattern 111. During the buffer layer deposition process, the buffer layer structure 120 may be crystal-grown with respect to the surface 111a of the protruding pattern 111. The buffer layer structure 120 may be crystal-grown with respect to the surface 111a of the protruding pattern 111 to fill the trench 115 formed in the insulating layer 150, and may be formed to a height higher than the insulating layer 150. As shown in FIG. 5E, an ART layer 120a that fills the trench 115 may be formed, and as shown in FIG. 5F, the ART layer 120a may be crystal-grown to form an NRE layer 120b. The ART layer 120a may correspond to a portion of the buffer layer formed to fill the trench 115, and the NRE layer 120b may correspond to a portion of the buffer layer formed at a height higher than the insulating layer 150 after filling the trench 115. In FIG. 5E, the ART layer 120a is illustrated as being formed to the same level as the insulating layer 150, but a region corresponding to the ART layer 120a is not limited thereto. The ART layer 120a may correspond to a level slightly higher than the insulating layer 150. In addition, in FIG. 5E, the ART layer 120a is depicted as being flat, but is not limited thereto. For example, the ART layer 120a may be formed in a convex shape.

In FIG. 5F, the NRE layer 120b is illustrated as having two inclined planes with a raised central portion, but embodiments are not limited thereto. The shape of the NRE layer 120b may vary depending on the crystal growth conditions such as a width of the trench 115, a growth speed, etc., and the shape of the light-emitting layer structure 130 epitaxially grown on the NRT layer 120b may be formed according to the shape of the NRT layer 120b. In FIGS. 1 to 4, FIGS. 5F to 5J, and embodiments described later, the NRT layer 120b is illustrated as having two inclined planes with a raised center portion, and the light-emitting layer structure 130 epitaxially grown has a corresponding shape, but this is only an example, and the shape of the laser device 101 is not limited thereto. The ART layer 120a and the NRE layer 120b may be formed continuously without an interlayer interface, or an interlayer interface may be formed therebetween.

The ART layer 120a and the NRE layer 120b may include a compound semiconductor material in which at least one element is different, or may include the same compound semiconductor material. At this time, the ART layer 120a and the NRE layer 120b may include a compound semiconductor material including two or more of Group III-V semiconductor materials, such as In, Ga, Al, As, or P. The ART layer 120a and the NRE layer 120b may include a multilayer structure of a compound semiconductor material including two or more of In, Ga, Al, As, or P. The ART layer 120a and the NRE layer 120b may include, for example, GaAs, InGaAs, or InP. However, embodiments are not limited thereto. The ART layer 120a may include, for example, GaAs. The NRE layer 120b may include, for example, InGaAs, for example, In_{0.25}GaAs. As another example, the ART layer 120a and the NRE layer 120b may include GaAs.

A seed layer may be further formed in the surface 111a of the protruding pattern 111. The seed layer may be crystal-grown in the surface 111a of the protruding pattern 111, and the ART layer 120a may be crystal-grown on the seed layer. In FIGS. 1 to 4, FIGS. 5E and 5F, and the diagrams below, the seed layer is omitted. The seed layer may include the same material as the ART layer 120a. For example, the seed layer may be a layer in which GaAs is crystal-grown at a low temperature on the surface 111a of the protruding pattern 111, and the ART layer 120a may be a layer in which GaAs is crystal-grown at a high temperature within the trench 115. When the seed layer is the same material as the ART layer 120a, the seed layer may not be distinguished from the ART layer 120a.

Referring to FIG. 5G, the light-emitting layer structure 130 including a quantum well structure 131 may be epitaxially grown on the NRE layer 120b of the buffer layer structure 120. The quantum well structure 131 of the light-emitting layer structure 130 may be formed by alternately growing a quantum barrier layer 131a of greater than or equal to about 3 nm and a quantum well layer 131b of greater than or equal to about 3 nm or twice of 3 nm. Each of the quantum barrier layer 131a and the quantum well layer 131b may independently include at least one of In, Ga, Al, As, P, Si, Zn, and C. For example, the quantum barrier layer 131a may include InₓGa_{y}Al_{z}As (0.00≤x≤0.50, 0.00≤y, z≤0.95), and the quantum well layer 131b may include InₓGa_{y}Al_{z}As (0.20≤x≤0.60, 0.00≤y, z≤0.95). For example, the quantum well layer 131b may include In, and the content of In may be in a range of about 0.20 to about 0.55, for example, about 0.45. The quantum barrier layer 131a may optionally include In, and the content of In may be in a range of 0.00 to about 0.45, for example, about 0.25. As an example, the quantum well structure 131 may be formed by alternating growth of the quantum barrier layer 131a including GaAs and the quantum well layer 131b including InGaAs, for example, In_{0.45}GaAs, twice or more. At this time, as described above, the thickness and In content of the quantum well layer 131b may vary depending on the width of the trench 115.

The emission wavelength band of the quantum well structure 131 may be adjusted by changing at least one of the shape, material, and thickness of the quantum well layer 131b, and the emission intensity may be adjusted by changing the number of layers of the quantum well layer 131b. In the quantum well structure 131 of the light-emitting layer structure 130, an area of the epitaxial growth region may vary depending on the width of the protruding pattern 111 and the trench 115 that accommodates the protruding pattern 111 so that, for example, the In content in the InGaAs quantum well layer 131b and the thickness of the InGaAs quantum well layer 131b may vary. As a result, an energy band difference of the InGaAs quantum well layer 131b/GaAs quantum barrier layer 131a may occur, and thus the emission wavelength characteristics may change. The quantum well structure 131 may be formed to generate light in a wavelength range of about 950 nm to about 1750 nm.

At least one of a first type semiconductor layer 125 and a first cladding layer 123 may be further formed between the buffer layer structure 120 and the quantum well structure 131. In addition, at least one of a second cladding layer 133 and a second type semiconductor layer 135 may be further formed on the quantum well structure 131. For example, the first type semiconductor layer 125, the first clad layer 123, the quantum well structure 131, the second clad layer 133, and the second type semiconductor layer 135 may be sequentially stacked on the NRE layer 120b. The light-emitting layer structure 130 formed in this manner may be substantially the same as the light-emitting layer structure 130 described above with reference to FIGS. 1 to 4.

Referring to FIG. 5H, a capping layer 137 may be formed on the light-emitting layer structure 130. The capping layer 137 may be formed to be adjacent to and surround the buffer layer structure 120 and the light-emitting layer structure 130 protruding above the insulating layer 150. As another example, the capping layer 137 may be formed to be adjacent to and surround only the light-emitting layer structure 130. The capping layer 137 may include a material including a predetermined dopant. The capping layer 137 may include, for example, a material including InGaP and a predetermined dopant. The capping layer 137 may be substantially the same as the capping layer 137 described with reference to FIG. 1.

Referring to FIG. 5I, in order to manufacture an electrical contact structure for the laser device 101, a passivation layer 140 may be formed to be adjacent to and surround the laser device 101. The passivation layer 140 may be provided to be adjacent to and surround the buffer layer structure 120 and the light-emitting layer structure 130. The passivation layer 140 may include, for example, polyimide, silicon oxide (SiO₂), or silicon nitride (SiN_{X}).

Referring to FIG. 5J, a trench may be formed in the passivation layer 140 to form a second type contact layer 160 to contact the light-emitting layer structure 130, and the second type contact layer 160 may be formed to fill the trench of the passivation layer 140 and extend using the passivation layer 140 as a support layer. In addition, the passivation layer 140 may be patterned to expose a portion of the silicon substrate 110, and a first type contact layer 165 may be formed on the exposed region of the silicon substrate 110. The passivation layer 140, the second type contact layer 160, and the first type contact layer 165 may be substantially the same as the passivation layer 140, the second type contact layer 160, and the first type contact layer 165 described with reference to FIG. 1.

FIGS. 6A to 6F show a method of manufacturing a multiple wavelength laser device 100 according to one or more embodiments. The method of manufacturing the laser device 101 described with reference to FIGS. 5A to 5J may be applied to the method of manufacturing the multiple wavelength laser device 100 according to one or more embodiments described with reference to FIGS. 6A to 6F.

Referring to FIGS. 6A and 6B, a silicon substrate 110 may be patterned to form a plurality of protruding pins 111′ that protrude with respect to a surface of the silicon substrate 110 and be spaced apart from each other, and an insulating layer 150 may be formed on the silicon substrate 110 to be provided on and cover regions between the protruding pins 111′. The insulating layer 150 may be formed to accommodate the plurality of protruding pins 111′.

The plurality of protruding pins 111′ may be formed such that at least one of a width and an arrangement period vary. For example, as illustrated in FIG. 6A, the plurality of protruding pins 111′ may be formed to have different widths each other. As in FIG. 6A, the plurality of protruding pins 111′ may be formed to have widths of W1, W2, W3, . . . , Wn, where n is an integer greater than or equal to 4, from the left side to the right side in the horizontal direction, so that the plurality of protruding pins 111′ may be formed to be W1≠W2≠W3≠ . . . ≠Wn. The protruding pins 111′ may be formed of the silicon substrate 110.

Referring to FIG. 6B, the insulating layer 150 may be formed on the silicon substrate 110 by high-temperature deposition, for example, to fill regions between the protruding pins 111′. The insulating layer 150 may include, for example, SiO₂ or Si₃N₄, and may be formed to have a thickness of, for example, greater than or equal to 100 nm.

As another example, a plurality of trenches 115 (see FIG. 6C) having widths corresponding to the plurality of protruding pins 111′ and exposing portions of the silicon substrate 110 may be formed in the insulating layer 150 on the silicon substrate 110, and the plurality of protruding pins 111′ may be formed on the silicon substrate 110 to fill at least a portion of the depth of each trench 115. The plurality of protruding pins 111′ may include a material including, for example, silicon.

In FIGS. 6A and 6B, the silicon substrate 110 and the insulating layer 150 may be substantially the same as the silicon substrate 110 and the insulating layer 150 described above with reference to FIGS. 1 to 4.

Referring to FIG. 6C, the plurality of protruding pins 111′ may be etched, for example, wet etched to a certain depth. By the etching, a structure in which a plurality of protruding patterns 111 protruding with respect to the silicon substrate 110 are accommodated in the trench 115 may be formed. At this time, a surface 111a of the protruding pattern 111 may be formed as a V-shaped groove. The surface 111a of the protruding pattern 111 may correspond to the Si (111) surface because it is a V-shaped groove, a Si (111) surface and a Si (−111) surface are substantially formed. The wet etching process may be performed, for example, using a KOH or TMAH solution as an etching medium.

For example, as described above, the plurality of protruding patterns 111 may have widths of W1, W2, W3, . . . , Wn, where n is an integer greater than or equal to 4, from the left side to the right side in the horizontal direction, corresponding to each of the plurality of protruding pins 111′, and the widths may be different from each other. For example, it may be W1≠W2≠W3≠ . . . ≠Wn. The plurality of trenches 115 may have widths corresponding to each protruding pattern 111 and may be spaced apart from each other. Accordingly, the plurality of protruding patterns 111 and the plurality of trenches 115 accommodating each protruding pattern 111 may have different widths (W1≠W2≠W3≠ . . . ≠Wn) each other.

Referring to FIGS. 6D and 6E, a plurality of buffer layer structures 120 may be crystal-grown with respect to each surface 111a of the plurality of protruding patterns 111. The buffer layer structure 120 may be crystal-grown with respect to the surface 111a of the protruding pattern 111 to fill the trench 115 formed in the insulating layer 150, and may be formed to a height greater than or equal to the insulating layer 150 in the vertical direction.

As in FIG. 6D, an ART layer 120a filling the trench 115 may be formed, and as in FIG. 6E, the ART layer 120a may be crystal-grown to form an NRE layer 120b. The ART layer 120a may correspond to a portion of the buffer layer formed to fill the trench 115, and the NRE layer 120b may correspond to a portion of the buffer layer formed at a height higher than the insulating layer 150 after filling the trench 115 in the vertical direction. In FIG. 6D, the ART layer 120a is illustrated as being formed to the same level as the insulating layer 150, but a region corresponding to the ART layer 120a is not limited thereto. The ART layer 120a may correspond to a level slightly higher than the insulating layer 150. In addition, in FIG. 6D, the ART layer 120a is illustrated as being flat, but is not limited thereto. For example, the ART layer 120a may be formed in a convex shape.

In FIG. 6E, the NRE layer 120b is illustrated as having a shape with two inclined planes 121 and 123 with a raised center portion but is not limited thereto. The shape of the NRE layer 120b may vary depending on the crystal growth conditions, such as a width of the trench 115 and an epitaxial growth speed, and the shape of the light-emitting layer structure 130 epitaxially grown on the NRE layer 120b may be formed according to the shape of the NRE layer 120b. In FIGS. 1 to 4, 5F to 5J, 6E to 6F, and embodiments described later, the NRE layer 120b is illustrated as having two inclined planes 121 and 123 with a raised center portion, and the epitaxially grown light-emitting layer structure 130 is illustrated as having a corresponding shape, but this is only an example, and the epitaxially grown structure of the laser device 101 is not limited thereto. The ART layer 120a and the NRE layer 120b may be formed continuously without an interlayer interface, or to have an interlayer interface therebetween.

The ART layer 120a and the NRE layer 120b may include a compound semiconductor material in which at least one element is different, or may include the same compound semiconductor material. At this time, the ART layer 120a and the NRE layer 120b may include a compound semiconductor material including two or more of Group III-V semiconductor materials, such as In, Ga, Al, As, or P. The ART layer 120a and the NRE layer 120b may include a multilayer structure of a compound semiconductor material including two or more of In, Ga, Al, As, or P. The ART layer 120a and the NRE layer 120b may include, for example, GaAs, InGaAs, or InP. However, it is not limited thereto. The ART layer 120a may include, for example, GaAs. The NRE layer 120b may include, for example, InGaAs, for example, In_{0.25}GaAs. As another example, the ART layer 120a and the NRE layer 120b may include GaAs.

Due to the plurality of buffer layer structures 120 being formed simultaneously during a deposition process, a layer thickness of each of the plurality of buffer layer structures 120 may vary depending on the width of the protruding pattern 111 and the trench 115 that accommodates the protruding pattern 111. As illustrated in FIG. 6C, when the widths of the plurality of protruding patterns 111 and the plurality of trenches 115 that accommodate each of the plurality of protruding patterns 111 increase from the left to the right, a thickness of the NRE layer 120b of each of the plurality of buffer layer structures 120 may become thinner from the left to the right, and a region where the NRE layer 120b of each of the plurality of buffer layer structures 120 is formed may become wider from the left to the right. For example, when the widths W1, W2, W3, . . . , Wn of the plurality of protruding patterns 111 and the plurality of trenches 115 that accommodate the plurality of protruding patterns 111 increase from the left to the right, that is, when W1<W2<W3< . . . <Wn, layer thicknesses of the plurality of buffer layer structures 120 formed above the insulating layer 150 that are each crystal-grown with respect to the plurality of protruding patterns 111 and the plurality of trenches 115 that accommodate the plurality of protruding patterns 111 may decrease from the left to the right and formed regions may widen from the left to the right.

As described above, the total process time for forming the plurality of buffer layer structures 120 is the same, but the time taken to form the ART layer 120a that fills each of the plurality of trenches 115 varies depending on the width of each trench 115, and thus, the thickness of the NRE layer 120b formed at a height greater than or equal to the insulating layer 150 may vary depending on the width of the trench 115. For example, a time to fill a trench increases as a wider width of the trench increases, the time for forming the NRE layer 120b formed at a height greater than or equal to the insulating layer 150 may decrease as the width of the trench 115 increases. Accordingly, the NRE layer 120b may be formed in a wider region with a thinner thickness as the width of the trench 115 increases.

For example, when the ART layers 120a filling the first to n^{th} trenches, respectively, are referred to as the first to n^{th} ART layers, and the NRE layers 120b crystal-grown with respect to the first to n^{th} ART layers, respectively, are referred to as the first to n^{th} NRE layers, and the process times for crystal-growing the first to n^{th} ART layers, respectively, are referred to as t1 to tn, because it takes more time to fill a trench with a wider width, there is a relationship of t1<t2<t3< . . . <tn. Accordingly, when the process time for crystal-growing of the first to n^{th} NRE layers is tR1 to tRn, there is a relationship of tR1>tR2>tR3> . . . >tRn. In addition, when the thicknesses of the first to n^{th} NRE layers formed are Th1, Th2, Th3, . . . , Thn, there is a relationship of Th1>Th2>Th3> . . . >Thn. This may be confirmed from the diagram in FIG. 6E. In addition, because the process time for forming each buffer layer structure 120 is the same, it may be t1+tR1=t2+tR2=t3+tR3= . . . =tn+tRn. Therefore, the smaller the width of the protruding pattern 111 and the trench 115 accommodating the protruding pattern 111, the shorter the process time for forming the ART layer 120a and the longer the process time for forming the NRE layer 120b. Conversely, the larger the width of the protruding pattern 111 and the trench 115 that accommodates the protruding pattern 111, the longer the process time for forming the ART layer and the shorter the process time for forming the NRE layer 120b. Accordingly, the NRE layer 120b formed at a height higher than the insulating layer 150 may be formed in a relatively narrow region with a thicker thickness as the width of the protruding pattern 111 and the trench 115 accommodating the protruding pattern 111 is smaller. In addition, the NRE layer 120b formed at a height higher than the insulating layer 150 may be formed in a wider region with a thinner thickness as the width of the protruding pattern 111 and the trench 115 accommodating the protruding pattern 111 is larger. In this way, a region and thickness where the buffer layer structure 120 is epitaxially grown may vary depending on the width of the protruding pattern 111 and the trench 115 accommodating the protruding pattern 111.

A seed layer may be further formed in the surface 111a of the protruding pattern 111. The seed layer may be crystal-grown in the surface 111a of the protruding pattern 111, and the ART layer 120a may be crystal-grown on the seed layer. In FIG. 6D, FIG. 6E, and the diagrams below, the seed layer is omitted. The seed layer may include the same material as the ART layer 120a. For example, the seed layer may be a layer of GaAs crystal-grown at a low temperature on the surface 111a of the protruding pattern 111, and the ART layer 120a may be a layer of GaAs crystal-grown at a high temperature within the trench 115. When the seed layer includes the same material as the ART layer 120a, the seed layer may not be distinguished from the ART layer 120a.

Referring to FIG. 6F, a plurality of light-emitting layer structures 130 including a quantum well structure 131 may be epitaxially grown on the NRE layer 120b of a buffer layer structure 120, and a capping layer 137 may be formed on each light-emitting layer structure 130, thereby forming an array of a plurality of laser device 101. The epitaxial growth of the light-emitting layer structure 130 on the NRE layer 120b of the buffer layer structure 120 and the formation of the capping layer 137 on the light-emitting layer structure 130 are as described with reference to FIGS. 5G and 5H. At least one of a first type semiconductor layer 125 and a first cladding layer 123 may be further formed between the buffer layer structure 120 and the quantum well structure 131. In addition, at least one of a second cladding layer 133 and a second type semiconductor layer 135 may be further formed on the quantum well structure 131. For example, the first type semiconductor layer 125, the first cladding layer 123, the quantum well structure 131, the second cladding layer 133, and the second type semiconductor layer 135 may be sequentially stacked on the NRE layer 120b. The light-emitting layer structure 130 may be substantially the same as the light-emitting layer structure 130 described above with reference to FIGS. 1 to 4.

As described with reference to FIGS. 51 and 5J, a passivation layer 140 may be formed, trenches may be formed in the passivation layer 140, a second type contact layer 160 for each laser device 101 may be formed by filling the trenches of the passivation layer 140, and extend using the passivation layer 140 as a support layer. In addition, the passivation layer 140 may be patterned to expose portions of the silicon substrate 110, and a first type contact layer 165 for each laser device 101 may be formed in the exposed regions of the silicon substrate 110. Forming the passivation layer 140, the second type contact layer 160, and the first type contact layer 165 may be substantially the same as described with reference to FIGS. 51 and 5J.

The capping layer 137 may be formed to be adjacent to and surround the buffer layer structure 120 and the light-emitting layer structure 130 protruding over the insulating layer 150. As another example, the capping layer 137 may be formed to be adjacent to and surround only the light-emitting layer structure 130. FIG. 6F simply illustrates that the capping layer 137 is positioned only on the light-emitting layer structure 130. Forming the capping layer 137 in each laser device 101 of the array of the plurality of laser devices 101 is substantially the same as described with reference to FIG. 5H.

Because each quantum well structure 131 of the plurality of light-emitting layer structures 130 has a different area of an epi-grown region depending on the width of the protruding pattern 111 and the trench 115 that accommodates the protruding pattern 111, for example, the In content in the InGaAs quantum well layer 131b and the thickness of the InGaAs quantum well layer 131b may vary, and thus, for example, an energy band difference of the InGaAs quantum well layer 131b/GaAs quantum barrier layer 131a may occur, and thus the emission wavelength characteristics may vary. Thereby, an array of a plurality of laser devices 101 having different emission wavelengths may be formed. Each quantum well structure 131 of the plurality of light-emitting layer structures 130 may be formed to generate laser light of a wavelength according to the characteristics of each quantum well structure 131 within a wavelength range of about 950 nm to about 1750 nm.

As shown in FIG. 6F, the quantum well layer 131b of the quantum well structure 131 epitaxially grown on the NRE layer 120b may be formed in a wider area with a thinner thickness as the width of the protruding pattern 111 and the trench 115 accommodating the protruding pattern 111 is larger, and the emission wavelength may be longer. Conversely, the quantum well layer 131b of the quantum well structure 131 epitaxially grown on the NRE layer 120b may be formed in a narrower region with a thicker thickness as the width of the protruding pattern 111 and the trench 115 accommodating the protruding pattern 111 is smaller, and the emission wavelength may be shorter. Accordingly, as in FIG. 4, when the widths of a plurality of protruding patterns 111 and the widths of the plurality of trenches 115 accommodating the plurality of protruding patterns 111 are different under the condition of, for example, W1<W2<W3< . . . <Wn, the emission wavelengths λ1, λ2, λ3, . . . , λn of the plurality of laser devices 101 including quantum well structures 131 formed with respect to each protruding pattern 111 and each trench 115 accommodating each protruding pattern 111 may have a relationship of λ1<λ2<λ3< . . . <λn. For example, the larger the width of the protruding pattern 111 and the trench 115 that accommodates the protruding pattern 111, the emission wavelength of the laser device 101 including the quantum well structure 131 formed with respect to the protruding pattern 111 and the trench 115 that accommodates the protruding pattern 111 may become longer.

According to the manufacturing method described with reference to FIGS. 5A to 5J and FIGS. 6A to 6F, the laser device 101 may be manufactured by crystal-growing a Group III-V compound semiconductor material in the silicon substrate 110, and the multiple wavelength laser device 100 including an array of a plurality of laser devices 101 having different emission wavelengths may be manufactured by varying the width of the protruding pattern 111 and the trench 115 that accommodates the protruding pattern 111.

FIGS. 5A to 5J and FIGS. 6A to 6F illustrate a method of manufacturing the laser device 101 illustrated in FIG. 1 and the multiple wavelength laser device 100 including the laser device 101 of FIG. 2, which may also be applied to manufacturing the laser device 103 illustrated in FIG. 3 and the multiple wavelength laser device 100 including the laser device 103. However, before forming the capping layer 137, a process of forming a current spreading layer 136 may be further added to be adjacent to and surround the buffer layer structure 120 and the light-emitting layer structure 130 on the insulating layer 150. In this case, the capping layer 137 may be formed to be adjacent to and surround the buffer layer structure 120 and the light-emitting layer structure 130 with the current spreading layer 136 therebetween.

FIG. 7 is a perspective view schematically showing a multiple wavelength laser device 200 according to one or more other embodiments. The multiple wavelength laser device 200 according to one or more other embodiments differs from the multiple wavelength laser device 100 described with reference to FIGS. 1 to 4 in that it further includes a waveguide coupler 280.

Referring to FIG. 7, the multiple wavelength laser device 200 may include a plurality of laser devices 101 formed in an array on a silicon substrate 110 and the waveguide coupler 280 arranged in a laser light emission direction to couple a plurality of laser lights emitted from the plurality of laser devices 101. The plurality of laser devices 101 formed as an array may be substantially the same as the multiple wavelength laser device 100 described with reference to FIGS. 1 to 4. The plurality of laser devices 101 and the waveguide coupler 280 may be formed on the same substrate, for example, the silicon substrate 110. A support structure 270 may be formed on the silicon substrate 110 on a laser light emission side of the plurality of laser devices 101, and the waveguide coupler 280 may be formed on the support structure 270.

The support structure 270 may be formed to be spaced apart from the array of the plurality of laser devices 101. The support structure 270 may be formed of, for example, an insulating material.

The waveguide coupler 280 may include a plurality of input waveguides having a plurality of input terminals facing a light emission surface of each laser device 101 corresponding to an array of a plurality of laser devices 101, an integrated waveguide portion that integrates paths of laser light traveling through the plurality of input waveguides and an output waveguide traveling the integrated laser light and having an output terminal 280a. A separation distance between the plurality of input terminals of the waveguide coupler 280 and light output surfaces of the plurality of laser devices 101 may be determined so that the laser light emitted from each laser device 101 is optically coupled to the waveguide coupler 280 to the maximum or at a ratio greater than an appropriate ratio. The waveguide coupler 280 may include a material having a small optical transmission loss for the emission wavelengths (λ1, λ2, λ3, . . . , λn) of the plurality of laser devices 101. The waveguide coupler 280 may include, for example, silicon. The paths of light input from the plurality of laser devices 101 to the waveguide coupler 280 may be integrated and be emitted from the output terminal 280a. When the emission wavelengths of an array of the plurality of laser devices 101 are λ1, λ2, λ3, . . . , λn, the laser light integrated in the waveguide coupler 280 and emitted through the output terminal 280a may have a wide wavelength range of λ1+λ2+λ3+ . . . +λn. For example, the multiple wavelength laser device 200 may be a broadband laser light source. As another example, the waveguide coupler 280 may have two or more output waveguides, and the integrated waveguide portion may be provided so that a plurality of laser lights traveling from the plurality of input waveguides are split and travel to two or more output waveguides. At this time, the integrated waveguide portion may be formed to integrate the traveling paths of the laser light into two or more so that the wavelength ranges of the laser lights output from the output terminals of the two or more output waveguides are the same, or at least partially different.

The waveguide coupler 280 and the support structure 270 supporting the waveguide coupler 280 may be manufactured by, for example, a CMOS process after directly growing the multiple wavelength laser device 100 on the silicon substrate 110. Accordingly, the multiple wavelength laser device 200 may reduce alignment issues between the laser device 101 and the waveguide coupler 280 and may be miniaturized.

FIGS. 8A to 8H show a method of manufacturing the multiple wavelength laser device 200 according to one or more embodiments. FIGS. 8A, 8B, 8C, and 8D are drawings substantially the same as FIGS. 6A, 6C, 6E, and 6F, respectively.

Referring to FIGS. 8A to 8D, an array of a plurality of laser devices 101 may be formed on the silicon substrate 110. The process of forming the array of the plurality of laser devices 101 on the silicon substrate 110 illustrated in FIGS. 8A to 8D is substantially the same as that described above with reference to FIGS. 6A to 6F, and therefore, it is briefly described herewith.

First, as shown in FIGS. 8A and 8B, the plurality of protruding pins 111′ protruding with respect to the surface of a silicon substrate 110 and spaced apart from each other may be formed, the insulating layer 150 may be formed on the silicon substrate 110 to be provided on and cover regions between the plurality of protruding pins 111′, and the plurality of protruding pins 111′ may be etched, for example, wet etched to a certain depth. As a result, a structure in which a plurality of protruding patterns 111 protruding with respect to the silicon substrate 110 are accommodated in the trench 115 may be formed. At this time, the surface 111a of the protruding pattern 111 may be formed as a V-shaped groove. The wet etching process may be performed, for example, using a KOH or TMAH solution as an etching medium. As another example, a plurality of trenches 115 having widths corresponding to the plurality of protruding pins 111′ and exposing the silicon substrate 110 may be firstly formed in the insulating layer 115 on the silicon substrate 110, and a plurality of protruding pins 111′ may be formed with a silicon material to fill at least a portion of the depth of each trench 115. Next, by etching, for example, wet etching, the plurality of protruding pins 111′ to a certain depth, a structure in which the plurality of protruding patterns 111 protruding with respect to the silicon substrate 110 are accommodated in the trench 115 may be formed.

The plurality of protruding pins 111′ may be formed so that at least one of the width and the arrangement period vary. For example, as illustrated in FIG. 8A, the plurality of protruding pins 111′ may be formed so as to have different widths. As illustrated in FIG. 8B, the plurality of protruding patterns 111 may have widths of W1, W2, W3, . . . , Wn, where n is an integer greater than or equal to 4, from the left side to the right side in the horizontal direction corresponding to each of the plurality of protruding pins 111′, and the plurality of trenches 115 may have widths corresponding to each of the protruding patterns 111 and may be spaced apart from each other. For example, the plurality of protruding patterns 111 and the plurality of trenches 115 that accommodate the plurality of protruding patterns 111 may have different widths (W1≠W2≠W3≠ . . . ≠Wn).

Next, as illustrated in FIG. 8C, a plurality of buffer layer structures 120 may be crystal-grown with respect to each surface 111a of the plurality of protruding patterns 111. The buffer layer structure 120 may be formed of, for example, an ART layer 120a and an NRE layer 120b. During a buffer layer deposition process, the ART layer 120a may be formed by filling the trench 115, and the NRE layer 120b may be formed by crystal-growth of the ART layer 120a.

When the widths of the plurality of protruding patterns 111 and the plurality of trenches 115 that accommodate the plurality of protruding patterns 111 increase from the left side to the right side in the horizontal direction (W1<W2<W3< . . . <Wn), a thickness of the NRE layer 120b of each of the plurality of buffer layer structures 120 may decrease from the left to the right (Th1>Th2>Th3> . . . >Thn).

As illustrated in FIG. 8D, each of a plurality of light-emitting layer structures 130 including a quantum well structure 131 may be epitaxially grown on the NRE layer 120b of each of the plurality of the buffer layer structures 120, and a capping layer 137 may be formed on each light-emitting layer structure 130, thereby forming an array of a plurality of laser devices 101.

Next, as shown in FIG. 8E, a passivation layer 140 may be formed to be adjacent to and surround each laser device 101 of the array of the plurality laser devices 101. The passivation layer 140 may be used as a support layer for forming a second type contact layer 160 as described above. The passivation layer 140 may be formed to be adjacent to and surround the buffer layer structure 120 and the light-emitting layer structure 130. Although not shown in FIG. 8E, as described with reference to FIGS. 51 and 5J, trenches may be formed in the passivation layer 140 to form the second type contact layer 160 to contact each light-emitting layer structure 130, and the second type contact layer 160 may be formed to fill the trenches of the passivation layer 140 and extend using the passivation layer 140 as a support layer. In addition, the passivation layer 140 may be patterned to expose portions of the silicon substrate 110, and a first type contact layer 165 for each laser device 101 may be formed in the exposed regions of the silicon substrate 110. The formation of the passivation layer 140, the second type contact layer 160, and the first type contact layer 165 may be substantially the same as described with reference to FIGS. 51 and 5J.

As another example, the process of forming the trenches in the passivation layer 140, forming the second type contact layer 160, and forming the first type contact layer 165 on regions of the silicon substrate 110 may be performed after the process of forming the waveguide coupler 280 described below with reference to FIGS. 8F to 8H.

In this way, after forming an array of the plurality of laser devices 101 on the silicon substrate 110, as shown in FIGS. 8F to 8H, a support structure 270 may be formed on the silicon substrate 110 on a laser light emission side of the plurality of laser devices 101, and a waveguide coupler 280 may be formed on the support structure 270. Therefore, the array of the plurality of devices 101 and the waveguide coupler 280 may be formed on the same silicon substrate 110.

As shown in FIGS. 8F and 8G, the support structure 270 may be formed to prepare for forming the waveguide coupler 280. This preparation may be, for example, a process of etching a location where the waveguide coupler 280 is to be formed, as shown in FIG. 8F. For example, during forming the protruding pin 111′ with respect to the silicon substrate 110, when a portion of a thickness of the silicon substrate 110 at a location where the waveguide coupler 280 is to be formed is removed by etching and the insulating layer 150 is formed overall on the silicon substrate 110, this preparation may be a process of removing at least a portion or all of the thickness of the insulating layer 150 at the location where the waveguide coupler 280 is to be formed by an etching process, for example, a dry etching process. As another example, during forming the protruding pin 111′ ahead, when a portion of the thickness of the silicon substrate at the location where the waveguide coupler 280 is to be formed is not etched, this preparation may be a process of etching the silicon substrate 110 to an appropriate thickness.

Next, as shown in FIG. 8G, the support structure 270 may be formed at a location where the waveguide coupler 280 is to be formed. The support structure 270 may be formed to a height for aligning the array of the plurality of laser devices 101 and the waveguide coupler 280. The support structure 270 may be formed of an insulating material. The support structure 270 may be formed to be spaced apart from the array of the plurality of laser devices 101.

Referring to FIG. 8H, the waveguide coupler 280 may be formed on the support structure 270 to correspond to the array of the plurality of laser devices 101. The waveguide coupler 280 may include a plurality of input waveguides having a plurality of input terminals facing the light emission surface of each laser device 101 corresponding to the array of a plurality of laser devices 101, an integrated waveguide portion that integrates paths of laser light traveling through the plurality of input waveguides, and an output waveguide traveling the integrated laser light and having an output terminal 280a. The waveguide coupler 280 may be formed so that a distance between the plurality of input terminals and light emission surfaces of the array of the plurality of laser devices 101 is a distance by which laser light emitted from each laser device 101 is optically coupled to the waveguide coupler 280 to the maximum or at a ratio greater than an appropriate ratio. The waveguide coupler 280 may include a material having a small optical transmission loss for the emission wavelengths λ1, λ2, λ3, . . . , λn of the plurality of laser devices 101. The waveguide coupler 280 may include, for example, silicon. A laser light of an integrated broadband wavelength (λ1+λ2+λ3+ . . . +λn) may be output through the output terminal 280a of the waveguide coupler 280. The waveguide coupler 280 may be substantially identical to the waveguide coupler 280 described with reference to FIG. 7.

An insulating layer may be formed on the support structure 270, the insulating layer may be patterned to form a trench pattern corresponding to the shape of a waveguide coupler 280, and the trench may be filled with an optical waveguide material to form the waveguide coupler 280. The insulating layer may include, for example, various types of insulating materials, such as oxides such as SiO₂, HfOₓ, or Al₂O₃. After the waveguide coupler 280 is formed, the insulating layer may or may not be removed.

In the above, the multiple wavelength laser devices 100 and 200 including the array of the plurality of laser devices 101 in which the widths of the plurality of protruding patterns 111 and the plurality of trenches 115 accommodating the plurality of protruding patterns 111 sequentially increase from the left to the right, and correspondingly, the emission wavelength sequentially increases from the left to the right, is described and illustrated, but is not limited thereto.

The array of the plurality of laser devices 101 may be formed to exhibit emission wavelength characteristics in which the emission wavelength sequentially decreases from the left side to the right side in the horizontal direction. In addition, the array of the plurality of laser devices 101 may be formed to exhibit emission wavelength characteristics of various arrangements other than the emission wavelength sequentially increasing or decreasing. The plurality of laser devices 101 having different emission wavelength characteristics may be arranged in various ways in terms of the emission wavelength.

For example, as in FIGS. 2, 4, 6C, and 8B, when the plurality of protruding patterns 111 and the plurality of trenches 115 accommodating the plurality of protruding patterns 111 have widths of W1, W2, W3, . . . , Wn from the left side to the right side in the horizontal direction, where n is an integer greater than or equal to 4, the width W2 of the trench adjacent to the trench having the width of W1 may be less than W1, and the width W3 of the trench adjacent to the trench having the width of W2 may be greater than W2 and smaller or greater than W1. The width W4 of the trench adjacent to the trench having the width of W3 may be smaller or greater than W3, smaller than W2, and smaller or greater than W1. In this way, the widths of the plurality of protruding patterns 111 and the plurality of trenches 115 accommodating the plurality of protruding patterns 111 may be formed in various width combinations, and an array of multiple laser devices 101 having a corresponding emission wavelength array combination may be formed.

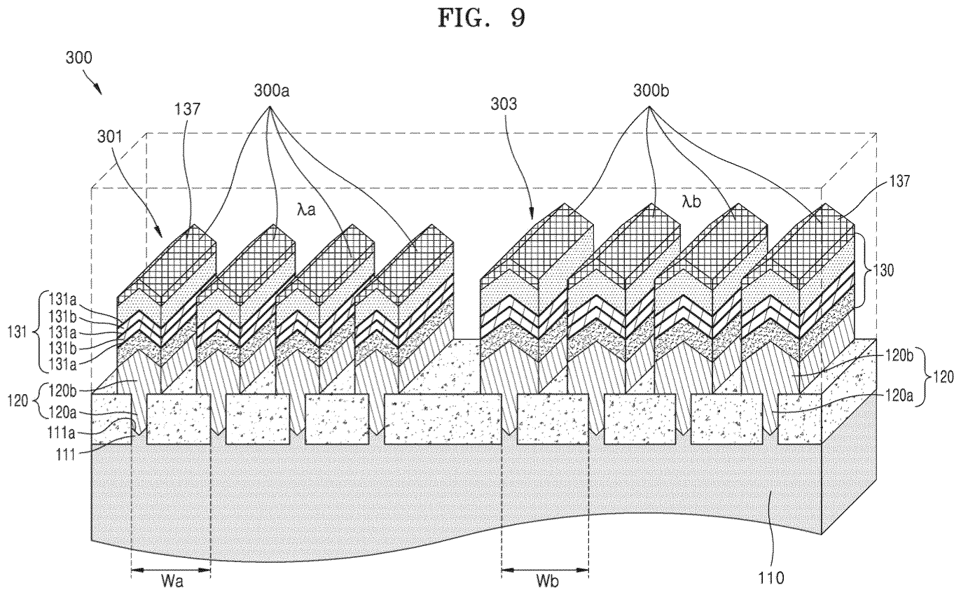

FIG. 9 is a perspective view schematically showing a multiple wavelength laser device 300 according to one or more embodiments. The multiple wavelength laser device 300 according to one or more embodiments differs from the multiple wavelength laser device 100 described with reference to FIGS. 1 to 4 in that the protruding patterns 111 and the trenches 115 accommodating the protruding pattern 111 have different arrangement periods.

Referring to FIG. 9, multiple wavelength laser device 300 may include a silicon substrate 110, a plurality of protruding patterns 111 formed to protrude from the silicon substrate 110 and having a change in arrangement cycle, an insulating layer 150 provided on the silicon substrate 110 and having a plurality of trenches 115 formed to accommodate the protruding patterns 111, and a plurality of laser devices 301 and 303. In the one or more embodiments, the arrangement periods of at least some of the plurality of protruding patterns 111 and the plurality of trenches 115 that accommodate the plurality of protruding patterns 111 are different from each other, and at least some of the plurality of laser devices 301 and 303 may be crystal-grown with respect to surfaces of the protruding patterns having different arrangement periods and thus may include a light-emitting layer structure having different emission wavelength characteristics.

For example, as shown in FIG. 9 as an example, the plurality of protruding patterns 111 and the plurality of trenches 115 that accommodate the plurality of protruding patterns 111 may include the plurality of protruding patterns 111 having a first arrangement period Wa and the plurality of trenches 115 that accommodate the plurality of protruding patterns 111 and the plurality of protruding patterns 111 having a second arrangement period Wb that is different from the first arrangement period Wa and the plurality of trenches 115 that accommodate the plurality of protruding patterns 111. The plurality of laser devices 301 and 303 may include a first laser device array 300a that emits laser light of a first wavelength λa and a second laser device array 300b that emits laser light of a second wavelength Ab different from the first wavelength Aa.

The first laser device array 300a may include a plurality of laser devices 301 provided to emit laser light of the first wavelength λa. The second laser device array 300b may include a plurality of laser devices 303 provided to emit laser light of the second wavelength λb. The plurality of laser devices 301 may be formed with respect to the plurality of protruding patterns 111 having a first arrangement period Wa and a plurality of trenches 115 accommodating the plurality of protruding patterns 111. The plurality of laser devices 303 may be formed with respect to the plurality of protruding patterns 111 having a second arrangement period Wb and the plurality of trenches 115 accommodating the plurality of protruding patterns 111.

At this time, when the plurality of trenches 115 having the first arrangement period Wa have a first width and the plurality of trenches 115 having a second arrangement period Wb have a second width, the first width and the second width may be the same as or different from each other. For example, the first laser device array 300a and the second laser device array 300b may be formed with respect to the plurality of trenches 115 having the same width. As another example, the first laser device array 300a and the second laser device array 300b may be formed with respect to the plurality of trenches 115 having different widths. As another example, each of the first laser device array 300a and the second laser device array 300b may be formed with respect to the plurality of trenches 115 having different widths.

The laser device 301 and the laser device 303 are substantially the same as the laser device 101 described with reference to FIGS. 1 to 4, respectively, and may have differences in emission wavelength characteristics. For example, the first wavelength λa and the second wavelength λb may correspond to any one or some of the wavelength bands of the emission wavelengths λ1, λ2, λ3, . . . , λn of the array of the plurality of laser devices 101 described above, but the first wavelength λa and the second wavelength λb may have different wavelength bands or at least some of the wavelength bands may be different. As another example, the first wavelength λa and the second wavelength λb may be different wavelengths from the emission wavelengths λ1, λ2, λ3, . . . , λn of the array of the plurality of laser devices 101 described above. As another example, the plurality of laser devices 301 of the first laser device array 300a may be provided to emit laser light of the same wavelength band, or at least some of them may be provided to emit laser light of different wavelength bands. For example, the first wavelength λa may be a single wavelength, or may include a plurality of wavelengths. The plurality of laser devices 301 of the second laser device array 300b may be provided to emit laser light of the same wavelength band, or at least some of them may be provide to emit laser light of different wavelength bands. For example, the second wavelength λb may be a single wavelength, or may include a plurality of wavelengths. However, even in this case, the first wavelength λa and the second wavelength λb may have different wavelength bands, or at least some wavelength bands may be different from each other.

The plurality of protruding patterns 111 and the plurality of trenches 115 accommodating the plurality of protruding patterns 111 of forming the first laser device array 300a may have an arrangement period of Wa, and the widths of the trenches 115 may be constant or may vary. The plurality of protruding patterns 111 and the plurality of trenches 115 accommodating the plurality of protruding patterns 111 of forming the second laser device array 300b may have an arrangement period of Wb different from Wa, and the widths of the trenches 115 may be constant or may vary. FIG. 9 shows an example in which the widths of the plurality of trenches 115 having an arrangement period of Wa and the widths of the plurality of trenches 115 having an arrangement period of Wb are the same.

FIG. 9 shows an example in which the first laser device array 300a includes four laser devices 301 and the second laser device array 300b includes four laser devices 303, but is not limited thereto. For example, the first laser device array 300a may include two laser devices 301, and in this case, the arrangement period Wa may correspond to the arrangement interval. The second laser device array 300b may include two laser devices 303, and in this case, the arrangement period Wb may correspond to the arrangement interval.

During the epi process for forming the first laser device array 300a and the second laser device array 300b, when the arrangement period of the trench 115 is relatively wide, the growth speed of the NRE layer 120b of the buffer layer structure 120 may vary, and accordingly, the predetermined element content and the thickness of the quantum well layer 131b of the quantum well structure 131 may vary. For example, when the quantum well layer 131b includes InGaAs, the In content in the quantum well layer 131b and the thickness of the quantum well layer 131b may vary.

In addition, in an epitaxial process for forming the first laser device array 300a and the second laser device array 300b, when the arrangement period of the trenches 115 is relatively narrow, the movement distance of molecules composing the quantum well layer 131b is shared between the trenches 115, and thus, the quantum well layer 131b may be formed to be relatively thin. On the other hand, when the arrangement period between the trenches 115 is wide, the movement distance of molecules composing the quantum well layer 131b is applied only to each trench 115, and thus, the thickness of the quantum well layer 131b may be relatively thick. For example, in forming an InGaAs quantum well layer 131b, when the arrangement period of the trenches 115 is relatively narrow, the movement distance of Ga, In, and As molecules is shared between the trenches 115, and thus, the InGaAs quantum well layer 131b may be formed to be relatively thin. When the arrangement period between trenches 115 is wide, the movement distance of Ga, In, and As molecules is applied only to each trench 115, and thus, thickness of the InGaAs quantum well layer 131b may become relatively thick. Accordingly, when the arrangement period between trenches 115 is relatively narrow, a short wavelength effect may occur, and when the arrangement period is wide, a long wavelength effect may occur.

As illustrated in FIG. 9, when the arrangement period Wb of the trench 115 forming the second laser device array 300b is wider than the arrangement period Wa of the trench 115 forming the first laser device array 300a, the second wavelength Ab of the laser light emitted from the second laser device array 300b may be a longer wavelength than the first wavelength λa of the laser light emitted from the first laser device array 300a.

The multiple wavelength laser device 300 of FIG. 9 may be manufactured by applying the method of manufacturing the multiple wavelength laser device 100 described with reference to FIGS. 6A to 6F, except that there is a change in the arrangement period of the protruding pattern 111 and the trench 115) that accommodates the plurality of protruding patterns 111.

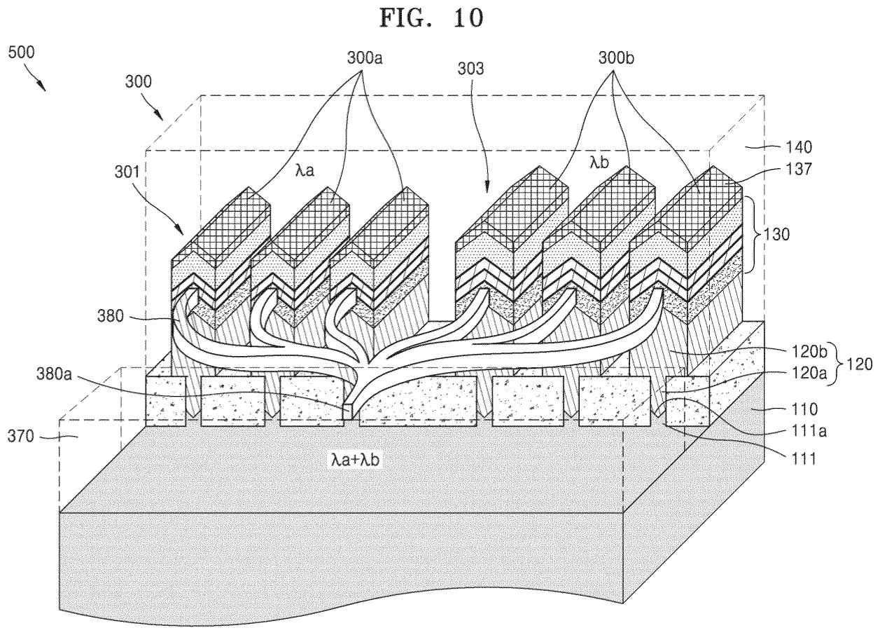

FIG. 10 is a schematic perspective view showing a multiple wavelength laser device 500 according to one or more embodiments. The multiple wavelength laser device 500 of the present embodiment differs from the multiple wavelength laser device 300 illustrated in FIG. 9 in that it further includes a waveguide coupler 380.

Referring to FIG. 10, the multiple wavelength laser device 500 may include a first laser device array 300a, a second laser device array 300b, and a waveguide coupler 380 arranged in a laser light emission direction to couple a plurality of laser lights of first wavelengths Aa and a plurality of laser lights of second wavelengths Ab emitted from the first and second laser device arrays 300a and 300b.

The first and second laser device arrays 300a and 300b and the waveguide coupler 380 may be formed on the same silicon substrate 110. A support structure 370 may be formed on the silicon substrate 110 in a laser light emission side of the first and second laser device arrays 300a and 300b, i.e., the multiple wavelength laser device 300, and the waveguide coupler 380 may be formed on the support structure 370. The waveguide coupler 380 and the support structure 370 may be substantially the same as the waveguide coupler 280 and the support structure 270 described with reference to FIG. 7. In FIG. 10, the first laser device array 300a includes three laser devices 301, the second laser device array 300b includes three laser devices 303, and input waveguides and an integrated waveguide portion of the waveguide coupler 380 are provided correspondingly, but embodiments are not limited thereto. The first laser device array 300a may include two laser devices 301 or four or more laser devices 301, and the second laser device array 300b may include two laser devices 303 or four or more laser devices 303, and the waveguide coupler 380 may be provided correspondingly.

Traveling paths of the light input from the first laser device array 300a and the second laser device array 300b to the waveguide coupler 380 may be integrated and be emitted to an output terminal 380a. When the emission wavelengths of the first laser device array 300a and the second laser device array 300b are each λa and λb, the laser light integrated in the waveguide coupler 380 and emitted through the output terminal 380a may have a broadband wavelength range of λa+λb. For example, the multiple wavelength laser device 500 may be a broadband laser light source. As another example, the waveguide coupler 380 may be provided with two output terminals, and may be provided to emit the first wavelength λa laser light emitted from the plurality of laser devices 301 of the first laser device array 300a through one output terminal, and to emit the second wavelength λb laser light emitted from the plurality of laser devices 303 of the second laser device array 300b through the other output terminal. As another example, the waveguide coupler 380 may be configured to have three or more output terminals.

In addition, the waveguide coupler 380 and the support structure 370 supporting the waveguide coupler 380 may be manufactured using, for example, a CMOS process after manufacturing of the multiple wavelength laser device 300 by directly growing on the silicon substrate 110. Therefore, the multiple wavelength laser device 500 may reduce alignment issues between the laser devices 301 of the first laser device array 300a and the laser devices 303 of the second laser device array 300b, and the waveguide coupler 380 and may be miniaturized.

The multiple wavelength laser device 500 of FIG. 10 may be manufactured by applying the method of manufacturing the multiple wavelength laser device 200 described above with reference to FIGS. 8A to 8H, except that there is a change in the arrangement period of the protruding pattern 111 and the trench 115 accommodating the protruding pattern 111.

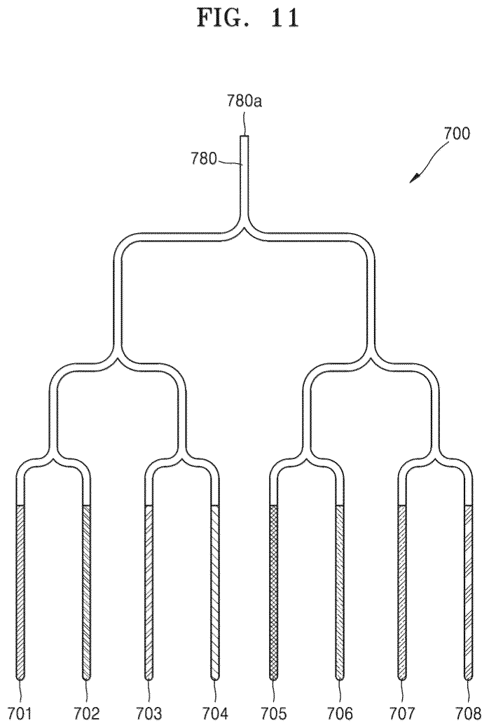

FIG. 11 is a schematic diagram showing a multiple wavelength laser device 700 according to one or more embodiments.

Referring to FIG. 11, the multiple wavelength laser device 700 according to one or more embodiments has a difference in a waveguide coupler 780 compared to the multiple wavelength laser devices 200 and 500 illustrated in FIG. 7 and FIG. 10.

Each of the laser devices 701, 702, 703, 704, 705, 706, 707, and 708 may be a single-wavelength laser device that emits laser light of different wavelength each other, like the array of the plurality of laser devices 101 of the multiple wavelength laser device 200 illustrated in FIG. 7. As another example, some of the laser devices 701 to 708 may correspond to the first laser device array 300a of the multiple wavelength laser devices 300 and 500 illustrated in FIG. 9 and FIG. 10, and the remaining may correspond to the second laser device array 300b. FIG. 11 shows an example in which the multiple wavelength laser device 700 includes eight laser devices 701 to 708 but is not limited thereto.

The waveguide coupler 780 may be provided to form a tree structure. For example, the waveguide coupler 780 may include a plurality of input waveguides having a plurality of input terminals facing a light emission surface of each laser devices 701 to 708 corresponding to the array of laser devices 701 to 708, an integrated waveguide portion that integrates the paths of laser light traveling through the plurality of input waveguides, and an output waveguide through which the integrated laser light travels and has an output terminal 780a. The integrated waveguide portion may be formed to form a tree structure. The waveguide coupler 780 may also be provided to have a plurality of output terminals.

In FIG. 11, a separation distance between the plurality of input terminals of the waveguide coupler 780 and the light emission surfaces of the laser devices 701 to 708 may exist so that the laser light emitted from each of the laser devices 701 to 708 may be optically coupled to the waveguide coupler 780 to maximum or at a ratio greater than an appropriate level. As another example, there may be no physical separation distance between the plurality of input terminals of the waveguide coupler 780 and the light emission surfaces of the laser devices 701 to 708.

The traveling paths of light input to the waveguide coupler 780 from the laser devices 701 to 708 may be integrated and the light may be output through the output terminal 780a. When the emission wavelengths of the laser devices 701 to 708 are λ1, λ2, λ3, . . . , λ8, the laser light integrated in the waveguide coupler 780 and output through the output terminal 780a may have a wide wavelength range of λ1+λ2+λ3+ . . . +λ8. In addition, when some of the laser devices 701 to 708 have an emission wavelength of λa and the remaining have an emission wavelength of Ab, the laser light integrated in the waveguide coupler 780 and emitted through the output terminal 780a may have a broadband wavelength range of λa+λb. In this way, the multiple wavelength laser device 700 may be a broadband laser light source.

As described above, like the multiple wavelength laser devices 100, 200, 300, 500, and 700, according to one or more embodiments, a multiple wavelength laser device may be manufactured by forming the protruding pattern 111 of various widths or arrangement periods and the trench 115 accommodating the protruding pattern 111 on a certain portion of the silicon substrate 110 and by selective growth using a Group III-V semiconductor material. For example, after performing a process of forming a trench that accommodates a protruding pattern having various widths with respect to an n-type silicon substrate, an array of a plurality of laser devices having different emission wavelengths each other may be formed by epitaxial growth of a Group III-V semiconductor material, thereby manufacturing a multiple wavelength IR laser having a range of, for example, about 950 nm to about 1750 nm. In addition, a broadband multiple wavelength laser device module may be manufactured by aligning an array of a plurality of laser devices with a waveguide coupler.

The multiple wavelength laser devices 100, 200, 300, 500, and 700 according to the various embodiments described above utilizes a principle that a difference in emission wavelength characteristics occurs due to different material compositions and/or layer thicknesses when epitaxially growing in regions with different widths or arrangement periods. For example, when applying InGa(Al)As as a material of the quantum well structure 131, the content of In and/or the thickness of the quantum well layer 131b may change, and therefore, a wavelength change is possible. For example, when the width of the trench 115 is different, a difference in epi growth speed within the trench 115 may occur, which may cause the change in In content within the InGa(Al)As, and the thickness of the quantum well layer 131b, etc., may change. In addition, depending on the arrangement period of the trench 115, when the movement distance of molecules composing the quantum well layer 131b is shared, the quantum well layer 131b may be formed thin, and when the movement distance of the molecules composing the quantum well layer 131b is not shared, the quantum well layer 131b may be formed relatively thick. Accordingly, when the arrangement period of the trench 115 is relatively narrow, a short-wavelength effect may occur, and when the arrangement period of the trench 115 is wide, a long-wavelength effect may occur.

For example, an In_{(1-x-y)}GaₓAl_{y}As band gap energy equation may be expressed as E_{g}(x,y)≈0.36+2.093y+0.629x+0.577y²+0.436x²+1.013xy−2.0xy (1−x−y) eV. However, it is not limited thereto. Considering the band gap energy equation, when the In content changes by 1%, the wavelength may vary by, for example, about 13 nm. In addition, when the thickness of the quantum well layer 131b changes by 1 nm, the wavelength may vary by, for example, about 3 nm.

Therefore, the multiple wavelength laser devices 100, 200, 300, 500, and 700 according to the embodiments utilizes the characteristic that the wavelength may be changed by changing the content of In and/or the thickness of the quantum well layer 131b etc. by changing the width and/or arrangement period of the protruding pattern 111 and the trench 115 that accommodates the protruding pattern 111.

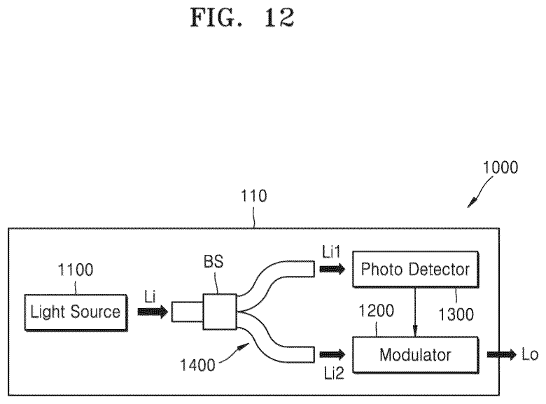

FIG. 12 is a block diagram showing a schematic configuration of a silicon photonics system 1000 according to one or more embodiments.

Referring to FIG. 12, the silicon photonics system 1000 may include a silicon substrate 110, a light source 1100 provided in the silicon substrate 110, and an optical transmission system provided on the silicon substrate 110 and transmitting light from the light source 1100. The optical transmission system may include a waveguide 1400. The optical transmission system may further include an optical modulator 1200 provided on the silicon substrate 110. The silicon photonics system 1000 may further include a photodetector 1300, etc., on the silicon substrate 110.

The light source 1100 may, for example, emit laser light in an infrared wavelength band. The light source 1100 may include any one of the multiple wavelength laser devices 100, 200, 300, 500, and 700 according to the various embodiments described above. For example, the light source 1100 may output a broadband infrared laser light within a range of about 950 nm to about 1750 nm.

The waveguide 1400 may be formed, for example, by a direct deposition process on the silicon substrate 110. The waveguide 1400 may split incident light Li into light Li1 and light Li2 and provide light Li1 and light Li2 to the photodetector 1300 and the optical modulator 1200, respectively. The waveguide 1400 may include a beam splitter BS for optical splitting. The beam splitter BS may split incident light into two, and at this time, the splitting ratios may be the same or different. As another example, the waveguide 1400 may be a Y-branching waveguide having one input terminal and two or more output terminals.

The photodetector 1300 may convert incident light Li1 into photoelectric and generate an electrical signal. The photodetector 1300 may be provided to absorb, for example, light of an infrared wavelength band to generate an electric signal. For example, a light absorption layer of the photodetector 1300 may include GaAs. In addition, the photodetector 1300 may include a light absorption layer of various materials so that the photodetector 1300 may detect light of an infrared wavelength band. The photodetector 1300 may be formed, for example, by a direct growth process on the silicon substrate 110. As another example, the photodetector 1300 may be manufactured separately and integrated into the silicon substrate 110.

The optical modulator 1200 may control an output light Lo by modulating incident light Li2. The output light Lo may be controlled on/off or on/off may be defined according to an intensity of the output light Lo. The optical modulator 1200 may be provided, for example, to modulate light of an infrared wavelength band. For example, an optical modulation layer of the optical modulator 1200 may include a quantum well structure including InGaAsP. Depending on a voltage applied to the optical modulator 1200, light of a specific wavelength band may be transmitted through the optical modulation layer or at least partially absorbed by the optical modulation layer. The optical modulator 1200 may be formed, for example, by a direct growth process on the silicon substrate 110. As another example, the optical modulator 1200 may be manufactured separately and integrated in the silicon substrate 110. The optical modulator 1200 may have a different semiconductor stack structure from the photodetector 1300, or the same semiconductor stack structure with the photodetector 1300.

In this way, an electric signal generated from the photodetector 1300 may depend on an intensity of light Li1, and whether light Li2 is output from the optical modulator 1200 may depend on the electric signal generated from the photodetector 1300. For example, a predetermined output light Lo may be generated according to light Li1 and light Li2 input from the light source 1100 to the photodetector 1300 and the optical modulator 1200.

Meanwhile, the silicon photonics system 1000 may further include a circuit configuration for applying an output electric signal of the photodetector 1300 as a voltage to the optical modulator 1200.

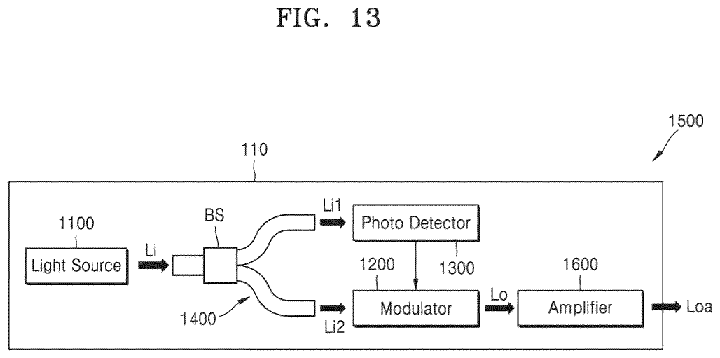

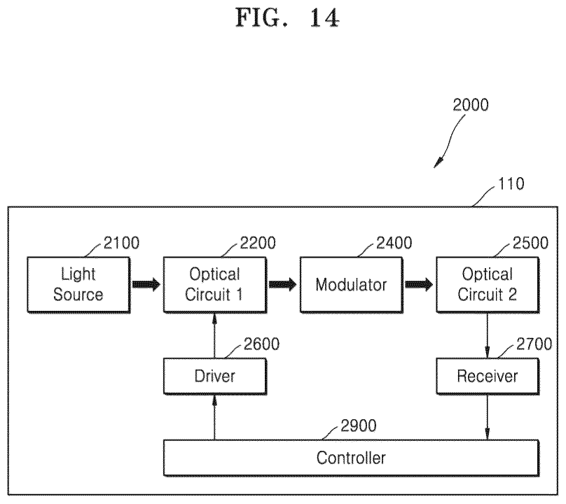

FIG. 13 is a block diagram showing a schematic configuration of a silicon photonics system 1500 according to one or more embodiments.

Referring to FIG. 13, the silicon photonics system 1500 according to one or more embodiments may further include an optical amplifier 1600 compared to the silicon photonics system 1000 of FIG. 12.

The optical amplifier 1600 may amplify output light Lo of the optical modulator 1200. The optical amplifier 1600 may include an optical gain medium, and when output light Lo is incident from the optical modulator 1200, the optical amplifier may output amplified output light Loa. The optical amplifier 1600 may be formed, for example, by a direct growth process in a silicon substrate 110. As another example, the optical amplifier 1600 may be manufactured separately and integrated in the silicon substrate 110.

FIG. 14 is a block diagram showing a schematic configuration of an optoelectronic device 2000 according to one or more embodiments. The optoelectronic device 2000 of FIG. 14 is included in an optical computing system by including a silicon photonics system, and may be, for example, a part of a configuration included in an Al accelerator.

Referring to FIG. 14, the optoelectronic device 2000 may include a silicon substrate 110, a light source 2100 provided in the silicon substrate 110, an optical modulator 2400 that outputs a judgment signal determined according to a form of light input from the light source 2100, and a controller 2900 that controls an input signal to the optical modulator 2400 and processes an output from the optical modulator 2400.

The light source 2100 may emit, for example, laser light in an infrared wavelength band. The light source 2100 may include any one of the multiple wavelength laser devices 100, 200, 300, 500, and 700 according to the various embodiments described above. For example, the light source 2100 may output broadband infrared laser light within a range of about 950 nm to about 1750 nm.

The optical modulator 2400 may control an output light by modulating incident light. The output light may be controlled to be on/off or on/off may be defined according to the intensity of the output light. The optical modulator 2400 may be provided to modulate, for example, light in an infrared wavelength band. For example, an optical modulation layer of the optical modulator 2400 may include a quantum well structure including InGaAsP. Depending on a voltage applied to the optical modulator 2400, light of a specific wavelength band may be transmitted through the optical modulation layer or be absorbed at least partially in the optical modulation layer. The optical modulator 2400 may have, for example, a structure grown directly in the silicon substrate 110. As another example, the optical modulator 2400 may be manufactured separately and integrated in the silicon substrate 110. The optical modulator 2400 may be provided as an array of a plurality of optical modulators.

The optoelectronic device 2000 may further include an optical circuit optically connected to an output terminal or an input terminal of the optical modulator 2400. For example, a first optical circuit 2200 may be provided between the light source 2100 and the optical modulator 2400, and a driver 2600 may be controlled by the controller 2900 and may apply a control signal to the first optical circuit 2200. Additionally, a second optical circuit 2500 may be provided at the output terminal of the optical modulator 2400, and a signal of the second optical circuit 2500 may be transmitted to the controller 2900 through a receiver 2700. The first optical circuit 2200, the optical modulator 2400, and the second optical circuit 2500 may be part of an optical transmission system.

The first optical circuit 2200 may have a configuration that modulates and splits light from the light source 2100. For example, the first optical circuit 2200 may have a configuration that modulates and splits light from the light source 2100 into light of the number and intensity required for input to the optical modulator 2400 and may include an optical waveguide structure including one or more beam splitters and one or more phase delayers.

The second optical circuit 2500 may convert output light from the optical modulator 2400 into an electrical signal. The second optical circuit 2500 may also amplify output light from the optical modulator 2400 and convert the light into an electrical signal.

The multiple wavelength laser devices 100, 200, 200, 300, 500, and 700 according to the various embodiments described above may be directly grown on the silicon substrate 110 in a portion requiring a multiple wavelength light source, and thus, may implement a small, low-power multiple wavelength laser device. The multiple wavelength laser devices 100, 200, 200, 300, 500, and 700 according to the various embodiments described above may be implemented in a chip size, and thus, may be implemented in a smaller size compared to a conventional external light source system or a light source using a bonding method.

In addition, the multiple wavelength laser devices 100, 200, 200, 300, 500, and 700 according to the various embodiments described above is implemented in a form directly manufactured on the silicon substrate 110, and thus, may be used as a multiple wavelength light source for a silicon photonics system or an optoelectronic device including the same, and the system applied in this way may be applied in various ways to systems requiring signal transmission, such as Chip-to-chip, Chip-to rack, and Rack-to-rack.

In addition, the multiple wavelength laser devices 100, 200, 200, 300, 500, and 700 according to the various embodiments described above may be directly manufactured on the silicon substrate 110, and thus, may be used in a wide range of optoelectronic devices requiring an ultra-small multiple wavelength light source, and may be manufactured in a chip-size including a multiple wavelength light source, and thus, it is possible to lower a system cost.

In addition, the multiple wavelength laser devices 200, 300, and 700 according to various embodiments including the waveguide couplers 280, 380, and 780 uses a light source directly grown based on silicon photonics instead of an external light source and a waveguide coupler, enabling system miniaturization and may be applied to silicon photonics systems requiring a broadband light source and the entire optical communication field. For example, the multiple wavelength laser devices 100, 200, 200, 300, 500, and 700 according to the various embodiments may be applied to various broadband silicon photonics systems to which an optical communication system of about 1550 nm wavelength band is applied, from chip-to-chip to data center applications.

For example, the multiple wavelength laser devices 100, 200, 200, 300, 500, and 700 according to the various embodiments may be applied as a multiple-wavelength light source to a light source integrated photonic integrated circuit, such as a memory-to-memory communication, an XPU (e.g., a central processing unit (CPU), a graphic processing unit (GPU), etc.)-to-memory communication, or an optical interconnection using a wavelength division multiplexing (WDM) method for XPU-to-XPU data transmission.

In addition, the multiple wavelength laser devices 100, 200, 200, 300, 500, and 700 according to the various embodiments may be applied to, for example, all mobile and stationary devices that require large-capacity, high-speed data transmission or wideband data transmission. The mobile and stationary devices may include, for example, automobiles, drones, robot cleaners, inspection equipment, industrial equipment, etc.

The multi-wavelength laser devices and its manufacturing method, and the silicon photonics system including the same have been described with reference to the embodiments illustrated in the drawings, but these are merely examples, and those skilled in the art will understand that various modifications and equivalent other embodiments are possible from this.

In addition, one or more embodiments may have the following configuration:

According to one or more embodiments, a multiple wavelength laser device may include
a plurality of protruding patterns protruding from a silicon substrate, at least one of a width and an arrangement period of the plurality of protruding patterns being different from each other;
an insulating layer on the silicon substrate, the insulating layer including a plurality of trenches configured to accommodates each of the plurality of protruding patterns, at least one of the width and the arrangement period of the plurality of trenches being different from each other;
a plurality of laser devices on a surface of each protruding pattern of each of the plurality of protruding patterns,
wherein each laser device of the plurality of laser devices includes:
a buffer layer structure formed by crystal growth with respect to the surface of each protruding pattern to fill each trench of the insulating layer, a height of the buffer layer structure being greater than or equal to a height of the insulating layer; and
a light-emitting layer structure on the buffer layer structure, the light-emitting layer structure having a quantum well structure configured to emit laser light of different emission wavelength based on at least one of the width and the arrangement period of the plurality of protruding patterns,
wherein at least one laser device of the plurality of laser devices has an emission wavelength different from at least one laser device of the remaining laser devices of the plurality of laser devices.

In the multiple wavelength laser device according to one or more embodiments, the plurality of protruding patterns and the plurality of trenches accommodating the plurality of protruding patterns may have different widths; and
the plurality of laser devices may include light-emitting layer structures that are crystal-grown with respect to each surface of a protruding pattern of the plurality of protruding patterns and have different emission wavelengths from each other.

In the multiple wavelength laser device according to one or more embodiments, the plurality of protruding patterns and the plurality of trenches accommodating each of the plurality of protruding patterns may be arranged at a regular interval.

In the multiple wavelength laser device according to one or more embodiments, the arrangement period of at least some of the plurality of protruding patterns and the plurality of trenches accommodating each of the plurality of protruding patterns may be different from each other; and

at least some of the plurality of laser devices may include a light-emitting layer structure that is crystal-grown with respect to a surface of a protruding pattern with different arrangement period and has different emission wavelength characteristics.

In the multiple wavelength laser device according to one or more embodiments, the plurality of protruding patterns and the plurality of trenches accommodating each of the plurality of protruding patterns may include:
a plurality of first protruding patterns and a plurality of first trenches accommodating each of the plurality of first protruding patterns having a first arrangement period; and
a plurality of second protruding patterns and a plurality of second trenches accommodating each of the plurality of second protruding patterns having a second arrangement period different from the first arrangement period,
wherein the plurality of laser devices may include:
a plurality of first laser devices corresponding to the plurality of first protruding patterns and the plurality of first trenches accommodating the plurality of first protruding patterns, the plurality of first laser devices configured to emit laser light of a first wavelength, and
a plurality of second laser devices corresponding to the plurality of second protruding patterns and the plurality of second trenches accommodating the plurality of second protruding patterns, the plurality of second laser devices configured to emit laser light of a second wavelength.

In the multiple wavelength laser device according to one or more embodiments, the plurality of first trenches may have a first width,
and the plurality of second trenches may have a second width,
and the first width and the second width may be the same or different from each other.

In the multiple wavelength laser device according to one or more embodiments, the plurality of protruding patterns and the plurality of trenches accommodating each of the plurality of protruding patterns may have the same width.

In the multiple wavelength laser device according to one or more embodiments, the light-emitting layer structure may further include
at least one of a first type semiconductor layer and a first cladding layer between the buffer layer structure and the quantum well structure, and
at least one of a second cladding layer and a second type semiconductor layer of an opposite conductivity type to the first type on the quantum well structure.

In the multiple wavelength laser device according to one or more embodiments, each surface of each protruding pattern of the plurality of protruding patterns may have a V-shaped groove.

In the multiple wavelength laser device according to one or more embodiments, the buffer layer structure may include a compound semiconductor material including two or more of In, Ga, Al, As, or P.

In the multiple wavelength laser device according to one or more embodiments, the buffer layer structure may include at least one of GaAs, InGaAs, and InP.

In the multiple wavelength laser device according to one or more embodiments, a quantum well structure of the light-emitting layer structure may include quantum barriers layer and quantum well layers alternately stacked multiple times, and
each of the quantum barrier layers and the quantum well layers independently may include at least one of In, Ga, Al, As, P, Si, Zn, and C, and may have a thickness of 3 nm or more.

In the multiple wavelength laser device according to one or more embodiments, the quantum barrier layers may include InₓGa_{y}Al_{z}As, where 0.00≤x≤0.50, 0.00≤y, z≤0.95, and
the quantum well layers may include InₓGa_{y}Al_{z}As, where 0.20≤x≤0.60, 0.00≤y, z≤0.95.

In the multiple wavelength laser device according to one or more embodiments, an indium (In) content of the quantum well layers may be in a range of about 0.20 to about 0.55, and

the In content of the quantum barrier layer may be in a range of about 0.00 to about 0.45.

In the multiple wavelength laser device according to one or more embodiments, each width of the plurality of trenches may be within a range of about 50 nm to about 500 nm, and
each emission wavelength of the plurality of laser devices may be within a range of about 950 nm to about 1750 nm.

In the multiple wavelength laser device according to one or more embodiments, the multiple wavelength laser device may further include a waveguide coupler on the silicon substrate and configured to couple the plurality of laser lights emitted from the plurality of laser devices, the waveguide coupler including a plurality of input terminals corresponding to the plurality of laser devices, respectively.

According to one or more embodiments, a method of manufacturing a multiple wavelength laser device, the method including: forming a plurality of protruding pins having at least one of a width and an arrangement period different from each other protruding from a silicon substrate and etching the plurality of protruding pins to a certain depth to form a plurality of protruding patterns having a width corresponding to each of the plurality of protruding pins and protruding from the silicon substrate;
forming an insulating layer on the silicon substrate, the insulating layer including a plurality of trenches configured to accommodate each of the plurality of protruding patterns, at least one of the width and the arrangement period of the plurality of trenches being different from each other; and
forming a plurality of laser devices on a surface of each protruding pattern of the plurality of protruding patterns,
wherein the forming of the plurality of laser devices includes:
forming a plurality of buffer layer structures that fill each of the plurality of trenches to a height equal to or higher than a height of the insulating layer by crystal growth with respect to each surface of the plurality of protruding patterns; and
forming a plurality of light-emitting layer structures formed the plurality of buffer layer structures and having a quantum well structure configured to emit laser light of different emission wavelengths based on at least one of the width and the arrangement period of the plurality of protruding patterns; and
wherein at least one laser device of the plurality of laser devices has an emission wavelength different from that of at least one laser device of the remaining laser devices.

In the method according to one or more embodiments, the plurality of protruding patterns and the plurality of trenches accommodating the plurality of protruding patterns may have different widths, and
the plurality of laser devices may include light-emitting layer structures configured to emit laser light of different emission wavelengths from each other by crystal-grown with respect to each surface of the plurality of protruding patterns.

In the method according to one or more embodiments, the plurality of protruding patterns and the plurality of trenches accommodating each of the plurality of protruding patterns may be arranged at a constant interval.

In the method according to one or more embodiments, the arrangement periods of at least some of the plurality of protruding patterns and the plurality of trenches accommodating the plurality of protruding patterns may be different from each other, and
at least some of the plurality of laser devices may include a light-emitting layer structure that is crystal-grown with respect to a surface of a protruding pattern with different arrangement period and has different emission wavelengths.

In the method according to one or more embodiments, the plurality of protruding patterns and the plurality of trenches accommodating each of the plurality of protruding patterns may include:
a plurality of first protruding patterns and a plurality of first trenches accommodating each of the plurality of first protruding patterns having a first arrangement period; and
a plurality of second protruding patterns and a plurality of second trenches accommodating each of the plurality of second protruding patterns having a second arrangement period different from the first arrangement period,
wherein the plurality of laser devices may include:
a plurality of first laser devices corresponding to the plurality of first protruding patterns and the plurality of first trenches accommodating the plurality of first protruding patterns, the plurality of first laser devices being configured to emit laser light of a first wavelength; and
a plurality of second laser devices corresponding to the plurality of second protruding patterns and the plurality of second trenches accommodating the plurality of second protruding patterns, the plurality of second laser devices being configured to emit laser light of a second wavelength.

In the method according to one or more embodiments, the plurality of first trenches may have a first width,
the plurality of second trenches may have a second width, and
the first width and the second width may be the same or different from each other.

In the method according to one or more embodiments, the plurality of protruding patterns and the plurality of trenches accommodating the plurality of protruding patterns may have the same width.

In the method according to one or more embodiments, the forming of the array of the plurality of laser devices further includes:
forming at least one of a first type semiconductor layer and a first cladding layer between the buffer layer structure and the quantum well structure; and
forming at least one of a second cladding layer and a second type semiconductor layer of an opposite conductivity type to the first type on the quantum well structure.

In the method according to one or more embodiments, the forming of the plurality of buffer layer structures may includes:
forming an aspect ratio trapping (ART) layer to fill each trench of the insulating layer; and
forming a nano-ridge epitaxy (NRE) layer by crystal growing of the ART layer.

In the method according to one or more embodiments, a surface of each protruding pattern of the plurality of protruding patterns may be a V-shaped groove, and
the V-shaped groove may be formed by a wet etching process.

In the method according to one or more embodiments, the buffer layer structure may include a compound semiconductor material including two or more of In, Ga, Al, As, and P.

In the method according to one or more embodiments, the buffer layer structure may include at least one of GaAs, InGaAs, and InP.

In the method according to one or more embodiments, the quantum well structure of the plurality of light-emitting layer structures may be formed by alternately stacking a quantum barrier layer and a quantum well layer multiple times, and
each of the quantum barrier layer and the quantum well layer may be formed to independently include at least one of In, Ga, Al, As, P, Si, Zn, and C, and have a thickness of 3 nm or more.

In the method according to one or more embodiments, the quantum barrier layer includes InₓGa_{y}Al_{z}As (0.00≤x≤0.50, 0.00≤y, z≤0.95), and
and the quantum well layer includes InₓGa_{y}Al_{z}As (0.20≤x≤0.60, 0.00≤y, z≤0.95).

In the method according to one or more embodiments, an indium (In) content of the quantum well layer may be in a range of about 0.20 to about 0.55, and
the In content of the quantum barrier layer may be in a range of about 0.00 to about 0.45.

In the method according to one or more embodiments, each width of the plurality of trenches may be within a range of about 50 to about 500 nm, and
each emission wavelength of the plurality of laser devices may be within a range of about 950 nm to about 1750 nm.

In the method according to one or more embodiments, the method of manufacturing a multiple wavelength laser device may further include removing a portion of the thickness of the silicon substrate at a position where a waveguide coupler is configured to be formed by etching;
forming a support structure on the position; and
forming the waveguide coupler on the support structure;
wherein the waveguide coupler may include a plurality of input terminals corresponding to the plurality of laser devices, the waveguide coupler being configured to couple a plurality of laser lights emitted from the plurality of laser devices.

According to one or more embodiments, a silicon photonics system including: a multiple wavelength laser device formed by crystal growth in a silicon substrate; and
an optical transmission system on the silicon substrate, the optical transmission system being configured to transmit laser light emitted from the multiple wavelength laser device,
wherein the multiple wavelength laser device includes:
a plurality of protruding patterns protruding from the silicon substrate, at least one of a width and an arrangement period of the plurality of protruding patterns being different from each other;
an insulating layer on the silicon substrate the insulating layer including a plurality of trenches configured to accommodate each of the plurality of protruding patterns, at least one of the width and the arrangement period of the plurality of trenches being different from each other; and
a plurality of laser devices on a surface of each protruding pattern of the plurality of protruding patterns,
wherein each laser device of the plurality of laser devices includes:
a buffer layer structure formed by crystal growth with respect to the surface of each protruding pattern to fill each trench of the insulating layer, a height of the buffer layer structure being greater than or equal to a height of the insulating layer; and
a light-emitting layer structure on the buffer layer structure, the light-emitting layer structure having a quantum well structure configured to emit laser light of different emission wavelength base on at least one of the width and the arrangement period of the plurality of protruding patterns;
wherein at least one laser device of the plurality of laser devices has an emission wavelength different from at least one laser device of the remaining devices of the plurality of laser devices.

In the silicon photonics system according to one or more embodiments, the multiple wavelength laser device may further include
a waveguide coupler on the silicon substrate and configured to couple a plurality of laser lights emitted from the plurality of laser devices, the waveguide coupler including a plurality of input terminals corresponding to the plurality of laser devices.

In the silicon photonics system according to one or more embodiments, the optical transmission system may further include
at least one of a waveguide configured to transmit laser light from the multiple wavelength laser device, and an optical circuit configured to modulate or split laser light from the multiple wavelength laser device.

According to the multiple wavelength laser device and the manufacturing method thereof according to one or more embodiments, by forming at least one of a width and an arrangement period of a plurality of protruding patterns formed to protrude from a silicon substrate and a plurality of trenches formed in an insulating layer to accommodate each of the plurality of protruding patterns different from each other, a quantum well structure of a light-emitting layer structure of a plurality of laser devices formed as an array by crystal growth with respect to a surface of each protruding pattern may be formed so that the emission wavelength characteristics differ according to at least one of the width and arrangement period. Accordingly, the multiple wavelength laser device according to one or more embodiments may be directly grown on a portion of the silicon substrate that requires a multiple wavelength light source, and a miniaturized, low-power multiple wavelength laser device may be implemented.

In addition, the multiple wavelength laser device according to one or more embodiments is implemented in a form directly manufactured on a silicon substrate, and may be used as a multiple wavelength light source of a silicon photonics system or an optoelectronic device including the same. The system applied in this way may be applied to various broadband silicon photonics systems to which optical communication systems are applied, and may be applied in various ways to systems requiring signal transmission such as Chip-to-chip, Chip-to rack, and Rack-to-rack.

In addition, the multiple wavelength laser device according to one or more embodiments may be directly manufactured on a silicon substrate to be used in all optoelectronic devices requiring an ultra-small multi-wavelength light source, and because chip-size manufacturing including the multi-wavelength light source is possible, system cost reduction is possible.

Therefore, embodiments should be considered from an illustrative rather than a restrictive perspective. The scope of the present specification is indicated by the claims, not the foregoing description, and all differences within the scope equivalent thereto should be interpreted as included.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims and their equivalents.

What is claimed is:

1. A multiple wavelength laser device comprising:
a plurality of protruding patterns protruding from a silicon substrate, at least one of a width and an arrangement period of the plurality of protruding patterns being different from each other;
an insulating layer on the silicon substrate, the insulating layer comprising a plurality of trenches configured to accommodate each of the plurality of protruding patterns, at least one of the width and the arrangement period of the plurality of trenches being different from each other; and
a plurality of laser devices on a surface of each protruding pattern of the plurality of protruding patterns,
wherein each laser device of the plurality of laser devices comprises:
a buffer layer structure formed by crystal growth with respect to the surface of each protruding pattern to fill each trench of the insulating layer, a height of the buffer layer structure being greater than or equal to a height of the insulating layer; and
a light-emitting layer structure on the buffer layer structure, the light-emitting layer structure having a quantum well structure configured to emit laser light of different emission wavelength based on at least one of the width and the arrangement period of the plurality of protruding patterns,
wherein at least one laser device of the plurality of laser devices has an emission wavelength different from at least one laser device of the remaining laser devices of the plurality of laser devices.

2. The multiple wavelength laser device of claim 1, wherein the plurality of protruding patterns and the plurality of trenches accommodating the plurality of protruding patterns have different widths, and
wherein the plurality of laser devices comprise light-emitting layer structures that are crystal-grown with respect to each surface of a protruding pattern of the plurality of protruding patterns and have different emission wavelengths from each other.

3. The multiple wavelength laser device of claim 1, wherein the plurality of protruding patterns and the plurality of trenches accommodating each of the plurality of protruding patterns comprise:
a plurality of first protruding patterns and a plurality of first trenches accommodating each of the plurality of first protruding patterns having a first arrangement period; and
a plurality of second protruding patterns and a plurality of second trenches accommodating each of the plurality of second protruding patterns having a second arrangement period different from the first arrangement period,
wherein the plurality of laser devices comprise:
a plurality of first laser devices corresponding to the plurality of first protruding patterns and the plurality of first trenches accommodating the plurality of first protruding patterns, the plurality of first laser devices configured to emit laser light of a first wavelength; and
a plurality of second laser devices corresponding to the plurality of second protruding patterns and the plurality of second trenches accommodating the plurality of second protruding patterns, the plurality of second laser devices configured to emit laser light of a second wavelength.

4. The multiple wavelength laser device of claim 1, wherein each surface of each protruding pattern of the plurality of protruding patterns has a V-shaped groove.

5. The multiple wavelength laser device of claim 1, wherein the quantum well structure of the light-emitting layer structure comprises quantum barrier layers and quantum well layers alternately stacked multiple times,
wherein the quantum barrier layers comprise InₓGa_{y}Al_{z}As, where 0.00≤x≤0.50, 0.00≤y, z≤0.95, and
wherein the quantum well layers comprise InₓGa_{y}Al_{z}As, where 0.20≤x≤0.60, 0.00≤y, z≤0.95.

6. The multiple wavelength laser device of claim 5, wherein an indium (In) content of the quantum well layers is in a range of 0.20 to 0.55, and
wherein the In content of the quantum barrier layers is in a range of 0.00 to 0.45.

7. The multiple wavelength laser device of claim 1, wherein each width of the plurality of trenches is within a range of 50 to 500 nm, and
wherein each emission wavelength of the plurality of laser devices is within a range of 950 nm to 1750 nm.

8. The multiple wavelength laser device of claim 1, further comprising:
a waveguide coupler on the silicon substrate and configured to combine a plurality of laser lights emitted from the plurality of laser devices, the waveguide coupler comprising a plurality of input terminals corresponding to the plurality of laser devices, respectively.

9. A method of manufacturing a multiple wavelength laser device, the method comprising:
forming a plurality of protruding pins having at least one of a width and an arrangement period different from each other protruding from a silicon substrate, etching the plurality of protruding pins to a certain depth to form a plurality of protruding patterns having a width corresponding to each of the plurality of protruding pins and protruding from the silicon substrate;
forming an insulating layer on the silicon substrate, the insulating layer comprising a plurality of trenches configured to accommodate each of the plurality of protruding patterns, at least one of the width and the arrangement period of the plurality of trenches being different from each other; and
forming a plurality of laser devices on a surface of each protruding pattern of the plurality of protruding patterns,
wherein the forming of the plurality of laser devices comprises:
forming a plurality of buffer layer structures that fill the plurality of trenches to a height equal to or higher than a height of the insulating layer by crystal growth with respect to each surface of the plurality of protruding patterns; and
forming a plurality of light-emitting layer structures formed the plurality of buffer layer structures and having a quantum well structure configured to emit laser light of different emission wavelengths based on at least one of the width and the arrangement period of the plurality of protruding patterns, and
wherein at least one laser device of the plurality of laser devices has a different emission wavelength from at least one laser device of the remaining laser devices.

10. The method of claim 9, wherein the plurality of protruding patterns and the plurality of trenches accommodating the plurality of protruding patterns have different widths, and
wherein the plurality of laser devices comprise light-emitting layer structures configured to emit laser light of different emission wavelengths from each other by crystal-growth with respect to each surface of the plurality of protruding patterns.

11. The method of claim 9, wherein the plurality of protruding patterns and the plurality of trenches accommodating each of the plurality of protruding patterns comprise:
a plurality of first protruding patterns and a plurality of first trenches accommodating each of the plurality of first protruding patterns having a first arrangement period; and
a plurality of second protruding patterns and a plurality of second trenches accommodating each of the plurality of second protruding patterns having a second arrangement period different from the first arrangement period,
wherein the plurality of laser devices comprise:
a plurality of first laser devices corresponding to the plurality of first protruding patterns and the plurality of first trenches accommodating the plurality of first protruding patterns, the plurality of first laser devices being configured to emit laser light of a first wavelength; and
a plurality of second laser devices corresponding to the plurality of second protruding patterns and the plurality of second trenches accommodating the plurality of second protruding patterns, the plurality of second laser devices being configured to emit laser light of a second wavelength.

12. The method of claim 9, wherein the forming of the plurality of buffer layer structures comprises:
forming an aspect ratio trapping (ART) layer to fill each trench of the insulating layer; and
forming a nano-ridge epitaxy (NRE) layer by crystal-growth of the ART layer.

13. The method of claim 9, wherein a surface of each protruding pattern of the plurality of protruding patterns is a V-shaped groove, and
wherein the V-shaped groove is formed by a wet etching process.

14. The method of claim 9, wherein the quantum well structure of the plurality of light-emitting layer structures is formed by alternately stacking a quantum barrier layer and a quantum well layer multiple times,
wherein the quantum barrier layer comprises InₓGa_{y}Al_{z}As, where 0.00≤x≤0.50, 0.00≤y, z≤0.95, and
wherein the quantum well layer comprises InₓGa_{y}Al_{z}As, where 0.20≤x≤0.60, 0.00≤y, z≤0.95.

15. The method of claim 14, wherein an indium (In) content of the quantum well layer is in a range of 0.20 to 0.55, and
wherein the In content of the quantum barrier layer is in a range of 0.00 to 0.45.

16. The method of claim 9, wherein each width of the plurality of trenches is within a range of 50 to 500 nm, and
wherein each emission wavelength of the plurality of laser devices is within a range of 950 nm to 1750 nm.

17. The method of claim 9, further comprising:
removing a portion of a thickness of the silicon substrate at a position where a waveguide coupler is configured to be formed by etching;
forming a support structure on the position; and
forming the waveguide coupler on the support structure,
wherein the waveguide coupler comprises a plurality of input terminals corresponding to the plurality of laser devices, the waveguide coupler being configured to couple a plurality of laser lights emitted from the plurality of laser devices.

18. A silicon photonics system comprising:
a multiple wavelength laser device formed by crystal growth in a silicon substrate; and
an optical transmission system on the silicon substrate, the optical transmission system being configured to transmit laser light emitted from the multiple wavelength laser device,
wherein the multiple wavelength laser device comprises:
a plurality of protruding patterns protruding from the silicon substrate, at least one of a width and an arrangement period of the plurality of protruding patterns being different from each other;
an insulating layer on the silicon substrate, the insulating layer comprising a plurality of trenches configured to accommodate each of the plurality of protruding patterns, at least one of the width and the arrangement period of the plurality of trenches being different from each other; and
a plurality of laser devices on a surface of each protruding pattern of the plurality of protruding patterns,
wherein each laser device of the plurality of laser devices comprises:
a buffer layer structure formed by crystal growth with respect to the surface of each protruding pattern to fill each trench of the insulating layer, a height of the buffer layer structure being greater than or equal to a height of the insulating layer; and
a light-emitting layer structure on the buffer layer structure, the light-emitting layer structure having a quantum well structure configured to emit laser light of different emission wavelength based on at least one of the width and the arrangement period of the plurality of protruding patterns,
wherein at least one laser device of the plurality of laser devices has an emission wavelength different from at least one laser device of the remaining laser devices of the plurality of laser devices.

19. The silicon photonics system of claim 18, wherein the multiple wavelength laser device further comprises:
a waveguide coupler on the silicon substrate and configured to couple a plurality of laser lights emitted from the plurality of laser devices, the waveguide coupler comprising a plurality of input terminals corresponding to the plurality of laser devices.

20. The silicon photonics system of claim 18, wherein the optical transmission system further comprises:
at least one of a waveguide configured to transmit laser light from the multiple wavelength laser device, and an optical circuit configured to modulate or split laser light from the multiple wavelength laser device.
